(19) United States
(12) Patent Application Publication
(10) Pub. No.: US 2026/0070779 A1
(43) Pub. Date: Mar. 12, 2026

(54) Electronic Structure, Inertial Measurement Unit, Electronic Apparatus, And Moving Object

(71) Applicant: SEIKO EPSON CORPORATION, Tokyo (JP)

(72) Inventors: Yoshinao YANAGISAWA, Minowa (JP); Makoto SAKURAI, Okaya (JP)

(21) Appl. No.: 19/325,973

(22) Filed: Sep. 11, 2025

(30) Foreign Application Priority Data
Sep. 12, 2024 (JP) 2024-158202

(51) Int. Cl. B81B 7/00; B81C 1/00

(52) U.S. Cl. CPC B81B 7/0083; B81C 1/0069; B81B 2201/0235; B81B 2201/0242; B81B 2203/0163; B81B 2203/0307; B81B 2203/04; B81B 2207/012; B81B 2207/07; B81C 2203/037

(57) ABSTRACT

An electronic structure includes a circuit element, and a functional element disposed at a position overlapping the circuit element in a plan view in a Z-axis direction along a Z-axis, where three mutually orthogonal axes are an X-axis, a Y-axis, and the Z-axis, in which, between the circuit element and the functional element, a first protrusion group including a plurality of first protrusions disposed in an X-axis direction along the X-axis and a second protrusion group including a plurality of second protrusions disposed in the X-axis direction are provided, the circuit element and the functional element are coupled through the first protrusion group and the second protrusion group, a gap is provided between the first protrusion group and the second protrusion group, and the gap includes a first space provided from an end of the circuit element on a negative side of the X-axis to an end of the circuit element on a positive side of the X-axis.

The present application is based on, and claims priority from JP Application Serial Number 2024-158202, filed Sep. 12, 2024, the disclosure of which is hereby incorporated by reference herein in its entirety.

### BACKGROUND

### 1. Technical Field

The present disclosure relates to an electronic structure, an inertial measurement unit, an electronic apparatus, and a moving object.

### 2. Related Art

In recent years, physical quantity sensors and vibrators manufactured using silicon micro electro mechanical system (MEMS) technology using silicon substrates have been developed. For example, JP-A-2019-039885 discloses a physical quantity sensor including a sensor element and an IC as a circuit element that is adhered onto the sensor element by an adhesive layer.

In the physical quantity sensor disclosed in JP-A-2019-039885, an adhesive layer is formed over the entire lower surface of the circuit element, and the circuit element is adhered onto the sensor element by this adhesive layer, and thus there is a concern that heat generated in the circuit element will be easily transferred to the sensor element.

### SUMMARY

According to an aspect of the present disclosure, there is provided an electronic structure including a circuit element, and a functional element disposed at a position overlapping the circuit element in a plan view in a Z-axis direction along a Z-axis, where three mutually orthogonal axes are an X-axis, a Y-axis, and the Z-axis, in which, between the circuit element and the functional element, a first protrusion group including a plurality of first protrusions disposed in an X-axis direction along the X-axis and a second protrusion group including a plurality of second protrusions disposed in the X-axis direction are provided, the circuit element and the functional element are coupled through the first protrusion group and the second protrusion group, a gap is provided between the first protrusion group and the second protrusion group, and the gap includes a first space provided from an end of the circuit element on a negative side of the X-axis to an end of the circuit element on a positive side of the X-axis.

According to an aspect of the present disclosure, there is provided an inertial measurement unit including the above-described electronic structure, in which the functional element is an inertial sensor element.

According to an aspect of the present disclosure, there is provided an electronic apparatus including the above-described electronic structure.

According to an aspect of the present disclosure, there is provided a moving object including the above-described electronic structure.

### BRIEF DESCRIPTION OF THE DRAWINGS

FIG. 1 is a cross-sectional view showing an example of a configuration of an electronic structure according to a first embodiment.

FIG. 2 is a plan view showing an example of a configuration of the electronic structure according to the first embodiment.

FIG. 3 is a graph showing a temperature change of an output signal of the electronic structure.

FIG. 4 is a cross-sectional view showing an example of a configuration of an angular velocity sensor element.

FIG. 5 is a diagram illustrating a vibration structure.

FIG. 6 is a cross-sectional view schematically showing an example of a functional element.

FIG. 7 is a plan view schematically showing a vibration structure.

FIG. 8 is a plan view schematically showing an example of the functional element.

FIG. 9 is a schematic plan view showing an example of the functional element.

FIG. 10 is a schematic cross-sectional view showing an example of the functional element.

FIG. 11 is a schematic cross-sectional view showing an example of the functional element.

FIG. 12 is a perspective view schematically showing an example of the functional element.

FIG. 13 is a cross-sectional view schematically showing an example of the electronic structure.

FIG. 14 is a cross-sectional view schematically showing an example of the electronic structure.

FIG. 15 is a diagram illustrating a coupling section.

FIG. 16 is a cross-sectional view schematically showing an example of the electronic structure.

FIG. 17 is a cross-sectional view schematically showing a bonding section.

FIG. 18 is a cross-sectional view schematically showing a bonding section.

FIG. 19 is a plan view schematically showing an example of the electronic structure.

FIG. 20 is a plan view schematically showing an example of the electronic structure.

FIG. 21 is a cross-sectional view showing an example of a configuration of an electronic structure according to a second embodiment.

FIG. 22 is a plan view showing an example of a configuration of the electronic structure according to the second embodiment.

FIG. 23 is a graph showing a temperature change of an output signal of the electronic structure.

FIG. 24 is a cross-sectional view showing an example of a configuration of an electronic structure according to a third embodiment.

FIG. 25 is a cross-sectional view showing an example of a configuration of an electronic structure according to a fourth embodiment.

FIG. 26 is a diagram schematically showing a case where a functional element is a physical quantity sensor element.

FIG. 27 is a cross-sectional view showing an example of a configuration of an electronic structure according to a fifth embodiment.

FIG. 28 is a cross-sectional view showing an example of a configuration of a functional element of an electronic structure according to a sixth embodiment.

FIG. 29 is an enlarged cross-sectional view showing a portion XXIX of the functional element.

FIG. 30 is an example of a functional block diagram of an electronic apparatus according to a seventh embodiment.

FIG. 31 is an exploded perspective view showing an embodiment of an inertial measurement unit as an example of the electronic apparatus according to the seventh embodiment.

FIG. 32 is a perspective view of a substrate provided in the inertial measurement unit.

FIG. 33 is a block diagram showing an example of a configuration of an embodiment of an inertial/satellite navigation system as an example of the electronic apparatus according to the seventh embodiment.

FIG. 34 is a diagram showing an example of an appearance of a smartphone as an example of an electronic apparatus.

FIG. 35 is a diagram showing an example of an appearance of a wrist-worn portable device as an example of an electronic apparatus.

FIG. 36 is a plan view of a wrist device according to an embodiment of a portable electronic apparatus.

FIG. 37 is a perspective view showing a configuration of an automobile as an example of a moving object according to an eighth embodiment.

### DESCRIPTION OF EMBODIMENTS

Hereinafter, preferred embodiments of the present disclosure will be described in detail with reference to the drawings. The embodiments to be described below do not unduly limit the contents of the present disclosure described in the scope of claims. Furthermore, not all of the configurations to be described below are necessarily essential components of the present disclosure.

### 1. First Embodiment

### 1.1. Electronic Structure

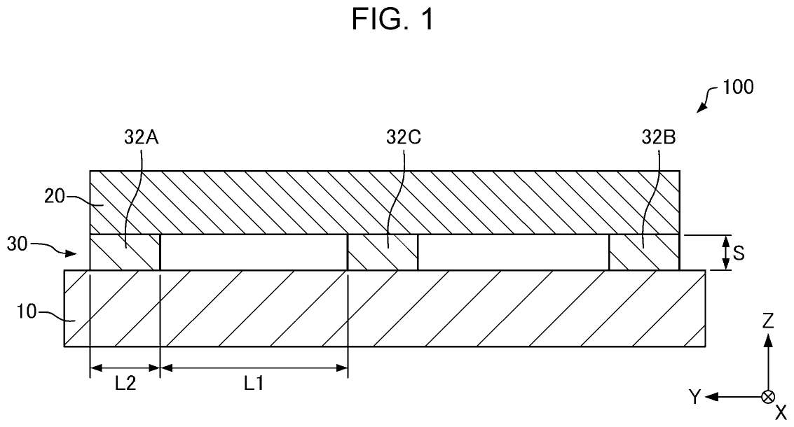

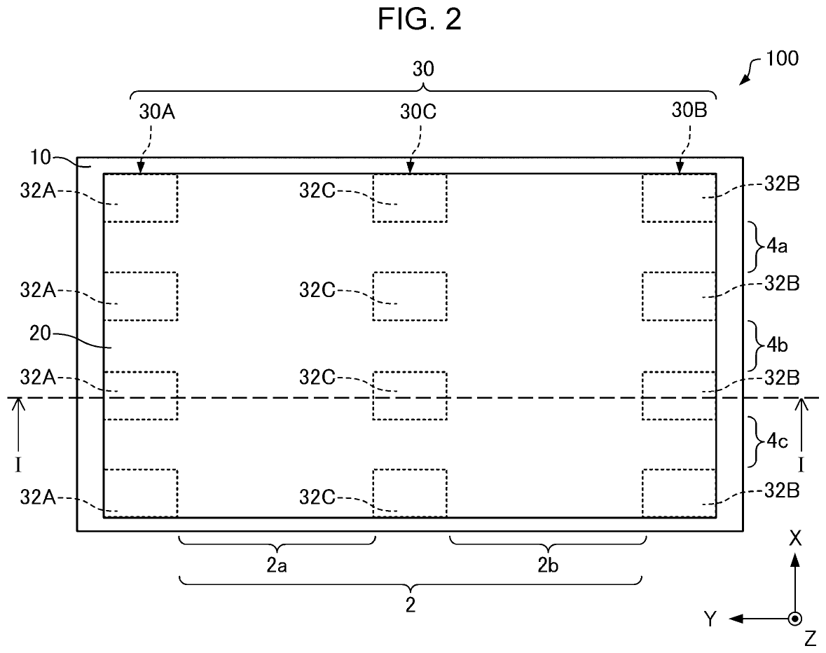

First, an electronic structure according to a first embodiment will be described with reference to the drawings. FIG. 1 is a cross-sectional view showing an example of a configuration of an electronic structure 100 according to the first embodiment. FIG. 2 is a plan view showing an example of a configuration of the electronic structure 100 according to the first embodiment. FIG. 1 is a cross-sectional view taken along line I-I of FIG. 2. In each of the drawings described below, an X-axis, a Y-axis, and a Z-axis are appropriately shown as three mutually orthogonal axes. In addition, a direction parallel to the X-axis is referred to as an “X-axis direction”, a direction parallel to the Y-axis is referred to as a “Y-axis direction”, and a direction parallel to the Z-axis is referred to as a “Z-axis direction”.

As shown in FIG. 1, the electronic structure 100 includes an integrated circuit (IC) 10 as a circuit element, and a functional element 20.

The functional element 20 is an element that has a predetermined function, and may be, for example, a physical quantity sensor element that has a function of detecting a desired physical quantity, or a vibration element that has a function of oscillating at a desired frequency. The functional element 20 may be, for example, a micro electro mechanical systems (MEMS) sensor element that detects a desired physical quantity, an inertial sensor element that detects angular velocity or acceleration, a MEMS vibration element that has the function of oscillating at a desired frequency, or any other type of MEMS element. As shown in FIG. 2, the functional element 20 is disposed at a position overlapping the IC 10 in a plan view in the Z-axis direction along the Z-axis. The functional element 20 is located on a +Z direction side of the IC 10. An example of the functional element 20 will be described later in “1.2. Functional Element”.

The IC 10 includes a drive circuit that drives the functional element 20, a detection circuit that detects a physical quantity based on a signal from the functional element 20, and an output circuit that converts the signal from the detection circuit into a predetermined signal and outputs the signal. The IC 10 may, for example, cause a vibration element that serves as the functional element 20 to oscillate. The IC 10 and the functional element 20 are electrically coupled. The IC 10 can control the functional element 20.

The IC 10 and the functional element 20 are coupled by a coupling section 30. The coupling section 30 includes a first protrusion group 30A, a second protrusion group 30B, and a third protrusion group 30C. The first protrusion group 30A, the second protrusion group 30B, and the third protrusion group 30C are provided between the IC 10 and the functional element 20.

The first protrusion group 30A includes a plurality of first protrusions 32A. The first protrusion 32A protrudes from the IC 10 in the +Z direction. In the shown example, the first protrusion group 30A includes four first protrusions 32A, but the number of first protrusions 32A is not particularly limited as long as the number is two or more. The plurality of first protrusions 32A are disposed along the X-axis. The plurality of first protrusions 32A are disposed discontinuously at intervals. That is, adjacent first protrusions 32A are spaced apart from each other. In the shown example, the intervals between adjacent first protrusions 32A are equal. That is, the plurality of first protrusions 32A are arranged at regular intervals. Although not shown, the plurality of first protrusions 32A do not necessarily have to be arranged at regular intervals.

The second protrusion group 30B includes a plurality of second protrusions 32B. The second protrusion 32B protrudes from the IC 10 in the +Z direction. In the shown example, the second protrusion group 30B includes four second protrusions 32B, but the number of second protrusions 32B is not particularly limited as long as the number is two or more. The plurality of second protrusions 32B are disposed along the X-axis. The plurality of second protrusions 32B are disposed discontinuously at intervals. That is, adjacent second protrusions 32B are spaced apart from each other. In the shown example, the intervals between adjacent second protrusions 32B are equal. That is, the plurality of second protrusions 32B are arranged at regular intervals. Although not shown, the plurality of second protrusions 32B do not necessarily have to be arranged at regular intervals.

The third protrusion group 30C includes a plurality of third protrusions 32C. The third protrusion 32C protrudes from the IC 10 in the +Z direction. In the shown example, the third protrusion group 30C includes four third protrusions 32C, but the number of third protrusions 32C is not particularly limited as long as the number is two or more. The plurality of third protrusions 32C are disposed along the X-axis. The plurality of third protrusions 32C are disposed discontinuously at intervals. That is, adjacent third protrusions 32C are spaced apart from each other. In the shown example, the intervals between adjacent third protrusions 32C are equal. That is, the plurality of third protrusions 32C are arranged at regular intervals. Although not shown, the plurality of third protrusions 32C do not necessarily have to be arranged at regular intervals.

In the shown example, the first protrusion 32A, the second protrusion 32B, and the third protrusion 32C have the same shape, but these shapes may be different.

The first protrusion group 30A is disposed at the end of the IC 10 on the +Y direction side. The second protrusion group 30B is disposed at the end of the IC 10 on the −Y direction side. The third protrusion group 30C is disposed between the first protrusion group 30A and the second protrusion group 30B.

A gap 2 is provided at a gap between the first protrusion group 30A and the second protrusion group 30B. The gap 2 includes a first space 2a and a second space 2b. Further, in the gap 2, the third protrusion group 30C is disposed.

The first space 2a is a space between the first protrusion group 30A and the third protrusion group 30C. The first space 2a is provided from the end of the IC 10 on the negative side of the X-axis to the end of the IC 10 on the positive side of the X-axis. That is, the first space 2a is a space that continues from the end of the IC 10 on the negative side of the X-axis to the end of the IC 10 on the positive side of the X-axis.

The second space 2b is a space between the second protrusion group 30B and the third protrusion group 30C. The second space 2b is provided from the end of the IC 10 on the negative side of the X-axis to the end of the IC 10 on the positive side of the X-axis. That is, the second space 2b is a space that continues from the end of the IC 10 on the negative side of the X-axis to the end of the IC 10 on the positive side of the X-axis.

The first protrusion 32A, the second protrusion 32B, and the third protrusion 32C form a row along the Y-axis. In the example shown in FIG. 2, the first protrusions 32A, the second protrusions 32B, and the third protrusions 32C are arranged in four rows. A space 4a is provided between the first row and the second row, a space 4b is provided between the second row and the third row, and a space 4c is provided between the third row and the fourth row. The space 4a is provided from the end of the IC 10 on the negative side of the Y-axis to the end of the IC 10 on the positive side of the Y-axis. The space 4b is provided from the end of the IC 10 on the negative side of the Y-axis to the end of the IC 10 on the positive side of the Y-axis. The space 4c is provided from the end of the IC 10 on the negative side of the Y-axis to the end of the IC 10 on the positive side of the Y-axis.

The first protrusion 32A, the second protrusion 32B, and the third protrusion 32C are, for example, metal bumps, conductive adhesives, wiring patterns, or the like. Moreover, the first protrusion 32A, the second protrusion 32B, and the third protrusion 32C may be formed by patterning a silicon oxide layer formed at the IC 10. An example of the coupling section 30 will be described later in “1.3. Coupling Section”.

When the temperature of the functional element 20 rises as the temperature of the IC 10 rises, the output signal of the electronic structure 100 may fluctuate. For example, when the functional element 20 is an angular velocity sensor element (also called a gyro sensor element), the temperature of the IC 10 may rise due to the current consumption at the activation of the IC 10, and the temperature of the functional element 20 may also rise accordingly. As the temperature of the functional element 20 rises in accordance with the temperature rise of the IC 10 in this manner, the output signal of the electronic structure 100 fluctuates even in a stationary state in which an angular velocity is not applied, resulting in a so-called temperature drift (also known as a bias drift or a bias shift). The temperature drift causes an error in the output signal.

Here, since the first space 2a is provided from the end of the IC 10 on the negative side of the X-axis to the end of the IC 10 on the positive side of the X-axis, gas flows more easily than when the first space 2a is a closed space, for example. Similarly to the first space 2a, the second space 2b has a tendency for gas to flow easily. Therefore, in the electronic structure 100, by providing the first space 2a and the second space 2b between the IC 10 and the functional element 20, the flow of gas such as atmosphere can be promoted in the first space 2a and the second space 2b. This can reduce the transfer of heat between the IC 10 and the functional element 20, thereby improving a heat insulation effect between the IC 10 and the functional element 20. Accordingly, for example, when the functional element 20 is an angular velocity sensor element, the temperature drift can be reduced.

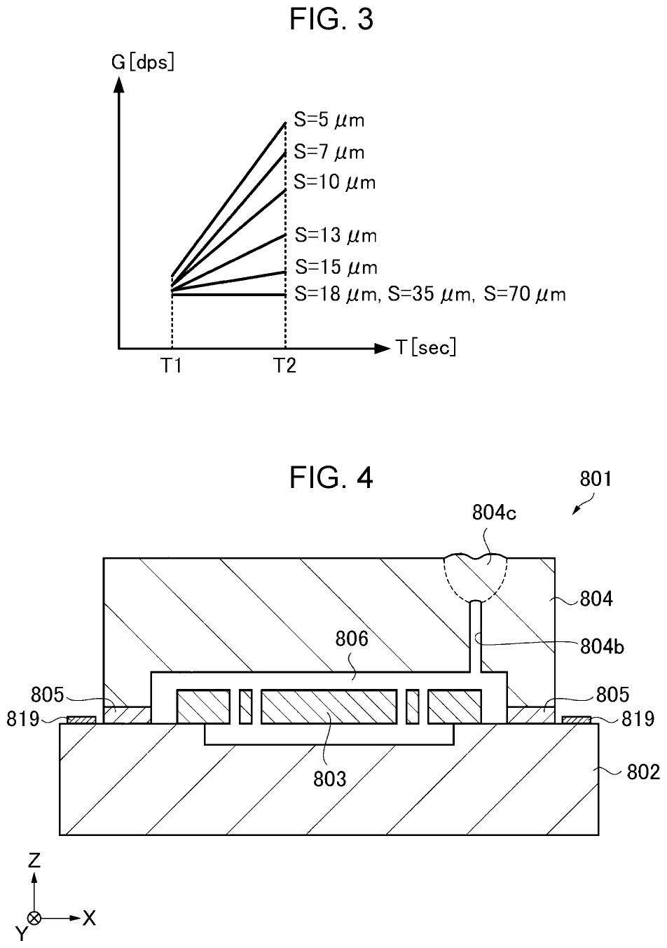

FIG. 3 is a graph showing a temperature change of an output signal of the electronic structure 100. Here, an interval S between the IC 10 and the functional element 20 is changed, and the temperature change of an output signal G degrees per second (dps) of the electronic structure 100 is measured. Also, the functional element 20 is an angular velocity sensor element, and the change in the output signal G of the electronic structure 100 when the temperature of the functional element 20 rises at a constant rate between time T1 and time T2 is plotted. The output signal G is an output signal in a stationary state in which an angular velocity is not applied.

As shown in FIG. 3, the change in the output signal G becomes small from the point where the interval S satisfies 15 μm≤S. Furthermore, when the interval S satisfies 18 μm≤S, the change in the output signal G is smaller. Further, when the interval S satisfies 18 μm≤S≤70 μm, the change in the output signal G is smaller. From these results, it is considered that when the interval S satisfies 18 μm≤S, the flow of gas can be promoted in the first space 2a and the second space 2b, and the heat insulation effect between the IC 10 and the functional element 20 can be improved. Furthermore, it is considered that when the interval S satisfies 18 μm≤S≤70 μm, the flow of gas can be further promoted in the first space 2a and the second space 2b, and the heat insulation effect between the IC 10 and the functional element 20 can be further improved.

When the interval between the first protrusion group 30A and the third protrusion group 30C is denoted by L1 and the width of the first protrusion group 30A is denoted by L2, 0.15<L2/L1<1.1 is satisfied, and preferably 0.25<L2/L1<0.85 is satisfied. Accordingly, it is possible to stably support the functional element 20 while ensuring the width of the first space 2a.

### 1.2. Functional Elements

### 1.2.1. Physical Quantity Sensor Elements

### Configuration of Angular Velocity Sensor Element

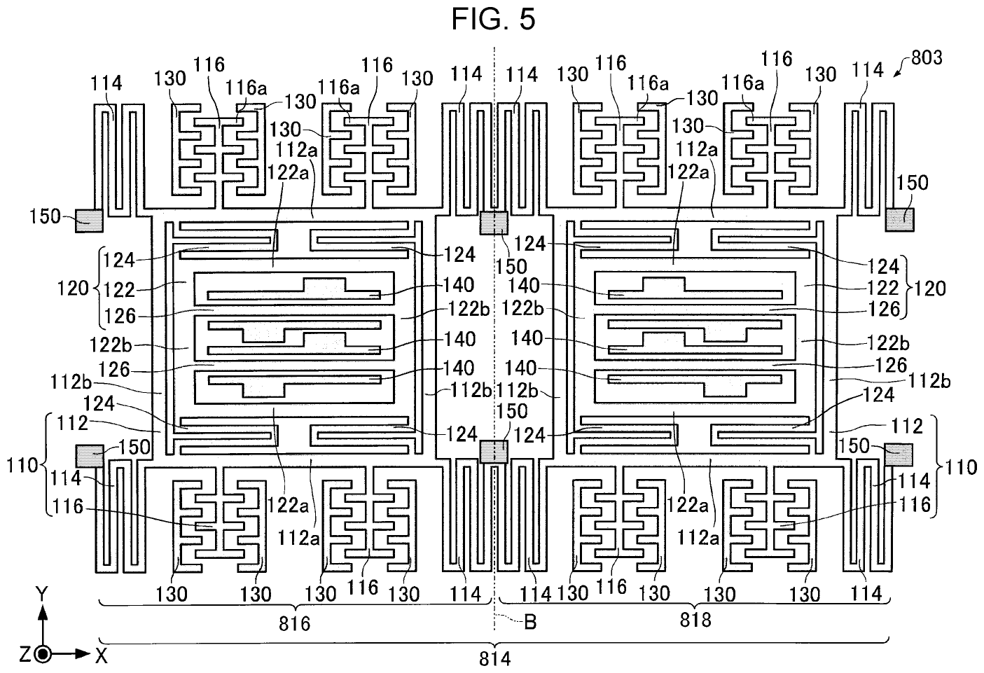

FIG. 4 is a cross-sectional view showing an example of a configuration of an angular velocity sensor element 801. FIG. 5 is a diagram illustrating a vibration structure 803.

As shown in FIG. 4, in the angular velocity sensor element 801 serving as an inertial sensor element, the vibration structure 803 is stacked on a base body (base) 802. The material of the base body 802 may be silicon, glass, quartz, or the like.

A lid 804 is installed on the base body 802. The material of the lid 804 is silicon. The lid 804 is bonded to the base body 802 by a bonding layer 805.

The angular velocity sensor element 801 includes the base body 802, the vibration structure 803, and the lid 804. The vibration structure 803 is housed in a space 806 between the base body 802 and the lid 804. The lid 804 is provided with a through hole 804b. The through hole 804b of the lid 804 is closed in the process of solidifying the melted portion after the peripheral region of the through hole 804b of the lid 804 is melted once. That is, the lid 804 includes a sealing section formed by sealing the through hole 804b with a solidified molten section 804c. As the molten section 804c closes the through hole 804b, the molten section 804c seals the space 806. The molten section 804c is a portion of the lid 804 and contains silicon. An electrode pad 819 is disposed on the base body 802 to be electrically coupled to the vibration structure 803.

As shown in FIG. 5, the vibration structure 803 includes a vibration section (movable section) 814, a driving fixed electrode 130, a detection fixed electrode 140, and a fixing section 150.

The vibration section (movable section) 814 is supported by the fixing section 150 fixed to the base body 802, and is disposed at a distance from the base body 802. The vibration section (movable section) 814 has a first vibration body 816 and a second vibration body 818. The first vibration body 816 and the second vibration body 818 are coupled to each other along the X-axis.

The first vibration body 816 and the second vibration body 818 have shapes that are symmetrical with respect to a boundary line B therebetween. The boundary line B is a straight line along the Y-axis. The configuration of the first vibration body 816 will be described below, and a description of the configuration of the second vibration body 818 will be omitted.

The first vibration body 816 has a driver 110 and a detector 120. The driver 110 has a driving supporter 112, a driving spring 114, and a driving movable electrode 116. The driving supporter 112 has a frame-like shape, and the detector 120 is disposed on the inner side of the driving supporter 112. The driving supporter 112 is configured by a first extending section 112a extending along the X-axis and a second extending section 112b extending along the Y-axis.

The driving spring 114 is disposed on the outer side of the driving supporter 112. One end of the driving spring 114 is coupled to the vicinity of a corner of the driving supporter 112. The corner of the driving supporter 112 is a coupling section between the first extending section 112a and the second extending section 112b. The other end of the driving spring 114 is coupled to the fixing section 150.

The first vibration body 816 is provided with four driving springs 114. The first vibration body 816 is supported by four fixing sections 150. The driving spring 114 expands and contracts in the X-axis direction, which is the vibration direction of the driver 110. As the driving spring 114 expands and contracts, the driving supporter 112 can be vibrated along the X-axis.

On the outer side of the driving supporter 112, the driving movable electrode 116 is disposed to be coupled to the driving supporter 112. The driving movable electrode 116 is coupled to the first extending section 112a of the driving supporter 112.

The driving fixed electrode 130 is disposed on the outer side of the driving supporter 112. The driving fixed electrode 130 is disposed to face the driving movable electrode 116. The driving fixed electrode 130 has a comb-like shape. The driving movable electrode 116 has a protrusion 116a that can be inserted between comb teeth of the driving fixed electrode 130.

When a voltage is applied to the driving fixed electrode 130 and the driving movable electrode 116, an electrostatic force can be generated between the driving fixed electrode 130 and the driving movable electrode 116. Accordingly, the driving spring 114 can expand and contract along the X-axis, and the driving supporter 112 of the driver 110 can be vibrated along the X-axis.

The detector 120 is coupled to the driver 110. The detector 120 can have a detection supporter 122, a detection spring 124, and a detection movable electrode 126.

The detection supporter 122 has, for example, a frame shape. In the shown example, the detection supporter 122 is configured by a third extending section 122a extending along the X-axis and a fourth extending section 122b extending along the Y-axis.

The detection spring 124 is disposed on the outer side of the detection supporter 122. The detection spring 124 couples the detection supporter 122 and the driving supporter 112. In the shown example, four detection springs 124 are provided on the first vibration body 816. The detection spring 124 expands and contracts in the Y-axis direction, which is the vibration direction of the detector 120. As the detection spring 124 expands and contracts, the detection supporter 122 of the detector 120 can be vibrated along the Y-axis.

The detection movable electrode 126 is coupled to the detection supporter 122 on the inner side of the detection supporter 122. In the shown example, the detection movable electrode 126 extends along the X-axis and is coupled to the two fourth extending sections 122b of the detection supporter 122.

The detection fixed electrode 140 is disposed on the inner side of the detection supporter 122. The detection fixed electrode 140 is fixed on the base body 802. In the shown example, a plurality of detection fixed electrodes 140 are provided, and are disposed to face each other with the detection movable electrode 126 interposed therebetween.

A first alternating voltage is applied between the driving movable electrode 116 and the driving fixed electrode 130 of the first vibration body 816, and a second alternating voltage that is 180 degrees out of phase with the first alternating voltage is applied between the driving movable electrode 116 and the driving fixed electrode 130 of the second vibration body 818. Accordingly, it is possible to vibrate the driver 110 of the first vibration body 816 and the driver 110 of the second vibration body 818 along the X-axis in opposite phases to each other and at a predetermined frequency. This vibration is called first vibration.

Since the detector 120 is coupled to the driver 110, the detector 120 also vibrates along the X-axis in association with the vibration of the driver 110. That is, the first vibration body 816 and the second vibration body 818 vibrate in opposite phases to each other along the X-axis. This vibration is called first vibration.

When the driver 110 of the first vibration body 816 and the driver 110 of the second vibration body 818 are performing the first vibration and an angular velocity ω around the Z-axis is applied to the angular velocity sensor element 801, the Coriolis force acts, and the detector 120 of the first vibration body 816 and the detector 120 of the second vibration body 818 are displaced along the Y-axis. As the detector 120 of the first vibration body 816 and the detector 120 of the second vibration body 818 are displaced along the Y-axis, a distance L between the detection movable electrode 126 and the detection fixed electrode 140 changes. Therefore, A capacitance between the detection movable electrode 126 and the detection fixed electrode 140 changes. In the angular velocity sensor element 801, by applying a voltage to the detection movable electrode 126 and the detection fixed electrode 140, the change in capacitance between the detection movable electrode 126 and the detection fixed electrode 140 can be detected and the angular velocity ω around the Z-axis can be obtained.

### Configuration of Acceleration Sensor Element

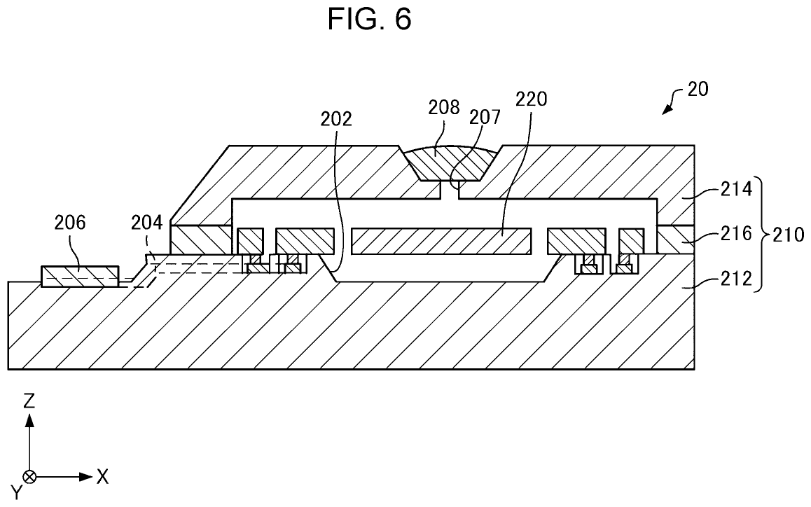

FIG. 6 is a cross-sectional view schematically showing an example of the functional element 20. The functional element 20 is an acceleration sensor element serving as an inertial sensor element, and the acceleration sensor element constitutes a Si-MEMS type acceleration sensor element that detects acceleration along the X-axis. As shown in FIG. 6, the acceleration sensor element serving as the functional element 20 has a container 210 having a base substrate 212 and a cap 214, and an X-axis sensor 220 accommodated in the container 210.

A recess 202 that opens upward is formed in the base substrate 212. The recess 202 functions as a clearance for preventing contact between the X-axis sensor 220 and the base substrate 212.

A wiring 204 for the X-axis sensor 220 is disposed on the base substrate 212. Further, the end of the wiring 204 is exposed to the outside of the container 210, and the exposed portion serves as a coupling terminal 206. Although not shown, the coupling terminal 206 may be electrically coupled to an electrode on the rear surface side by a through electrode or the like.

The base substrate 212 is formed of, for example, a glass material containing alkali metal ions (mobile ions). This allows the X-axis sensor 220, which is formed of a silicon substrate, to be firmly bonded to the base substrate 212 by anodic bonding. The constituent material of the base substrate 212 is not limited to a glass material, and may be, for example, a high-resistance silicon material. In this case, the base substrate 212 and the X-axis sensor 220 can be bonded together through, for example, a resin-based adhesive, glass paste, a metal layer, or the like.

The cap 214 has a recess that opens to the lower surface, and is bonded to the base substrate 212 such that the recess forms an internal space. The cap 214 is formed of a silicon substrate. The cap 214 and the base substrate 212 are airtightly bonded together using a glass frit 216. Furthermore, the cap 214 is provided with a stepped sealing hole 207 that penetrates to the outside. The sealing hole 207 is sealed with a molten metal 208, for example, a molten gold-germanium alloy (AuGe), with the internal space being filled with a nitrogen atmosphere.

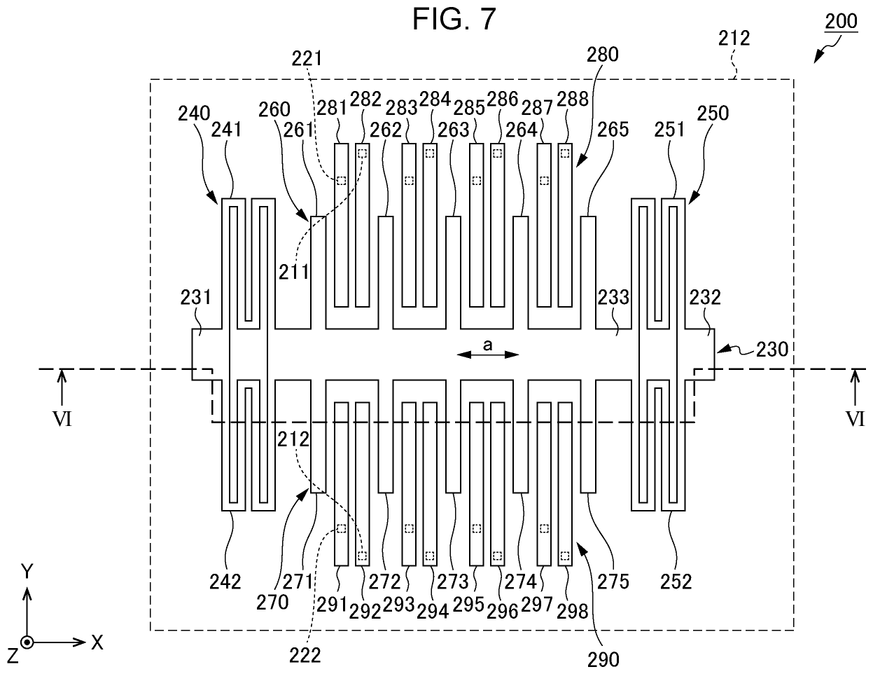

FIG. 7 is a plan view schematically showing a vibration structure 200 as the X-axis sensor 220. FIG. 6 is a cross-sectional view taken along line VI-VI in FIG. 7. For convenience, the X-axis sensor 220 is shown in a simplified manner in FIG. 6.

As shown in FIG. 7, the vibration structure 200 includes a vibration section (movable section) 230, a fixed electrode section 280, and a fixed electrode section 290. The vibration section 230 includes fixing sections 231 and 232, a movable beam 233, coupling sections 240 and 250, and movable electrode sections 260 and 270. In the present embodiment, the acceleration sensor element detects acceleration in the X-axis direction.

The fixing sections 231 and 232, the movable beam 233, the coupling sections 240 and 250, and the movable electrode sections 260 and 270 of the vibration section 230 are integrally formed. The fixing sections 231 and 232 are each bonded to the base substrate 212.

The movable beam 233 is disposed between the fixing section 231 and the fixing section 232. The movable beam 233 has an elongated shape extending in the X-axis direction, for example. The shape of the movable beam 233 is determined according to the shape and size of each portion constituting the vibration section 230, and is not limited to the above-described shape.

The vibration structure 200 is formed of a silicon substrate doped with impurities such as phosphorus or boron, and the silicon substrate has electrical conductivity.

The movable beam 233 is coupled to the fixing sections 231 and 232 through the coupling sections 240 and 250. The coupling sections 240 and 250 couple the movable beam 233 to the fixing sections 231 and 232 to be capable of displacement.

The coupling section 240 is configured with two beams 241 and 242. The beams 241 and 242 each have a shape that extends in the X-axis direction while meandering in the Y-axis direction. Similarly, the coupling section 250 is configured with two beams 251 and 252 that extend in the X-axis direction while meandering in the Y-axis direction. Accordingly, the movable beam 233 is configured to be displaceable in the X-axis direction relative to the base substrate 212 as indicated by an arrow a, while elastically deforming the coupling sections 240 and 250. A resonant frequency of the movable beam 233 is, for example, about several kHz.

The movable electrode section 260 is disposed to face the fixed electrode section 280 at an interval. In addition, the movable electrode section 270 is disposed to face the fixed electrode section 290 at an interval.

The movable electrode section 260 protrudes in the +Y direction from the movable beam 233 and includes a plurality of movable electrode fingers 261, 262, 263, 264, and 265 arranged in a comb-like shape. Similarly, the movable electrode section 270 protrudes from the movable beam 233 in the −Y direction, and includes a plurality of movable electrode fingers 271, 272, 273, 274, and 275 arranged in a comb-like shape.

The fixed electrode section 280 includes a plurality of fixed electrode fingers 281, 282, 283, 284, 285, 286, 287, and 288 arranged in a comb-like shape and spaced apart from each other to mesh with the plurality of movable electrode fingers 261 to 265 of the movable electrode section 260 at intervals.

When the size of the gap between the movable electrode fingers 261 to 265 of the movable electrode section 260 and the first fixed electrode fingers 282, 284, 286, and 288 and the second fixed electrode fingers 281, 283, 285, and 287 of the fixed electrode section 280 changes, the size of the capacitance between the movable electrode section 260 and the fixed electrode section 280 changes. Since the first fixed electrode finger and the second fixed electrode finger of the fixed electrode section 280 are electrically coupled to different wiring sections, the capacitance between the first fixed electrode finger of the fixed electrode section 280 and the movable electrode section 260, and the capacitance between the second fixed electrode finger of the fixed electrode section 280 and the movable electrode section 260 can be measured separately.

Similarly, when the size of the gap between the movable electrode fingers 271 to 275 of the movable electrode section 270 and the first fixed electrode fingers 292, 294, 296, 298 and the second fixed electrode fingers 291, 293, 295, 297 of the fixed electrode section 290 changes, the size of the capacitance between the movable electrode section 270 and the fixed electrode section 290 changes. Since the first fixed electrode finger and the second fixed electrode finger of the fixed electrode section 290 are electrically coupled to different wiring sections, the capacitance between the first fixed electrode finger of the fixed electrode section 290 and the movable electrode section 270, and the capacitance between the second fixed electrode finger of the fixed electrode section 290 and the movable electrode section 270 can be measured separately.

As described above, the vibration structure 200 detects the change in capacitance between the movable electrode sections 260 and 270 and the fixed electrode sections 280 and 290, thereby obtaining the acceleration in the X-axis direction in the IC 10.

In the above, the case has been described in which the functional element 20 constitutes an X-axis acceleration sensor element that detects acceleration along the X-axis, but the functional element 20 may also constitute an Z-axis acceleration sensor element that detects acceleration along the Z-axis, or constitute a Y-axis acceleration sensor element that detects acceleration along the Y-axis. Further, the functional element 20 may constitute a three-axis acceleration sensor that accommodates an X-axis acceleration sensor element, a Y-axis acceleration sensor element, and a Z-axis acceleration sensor element in one internal space.

In addition, in the above, the case has been described in which the functional element 20 constitutes a gyro sensor element or an acceleration sensor element as an inertial sensor, but the functional element 20 may also be provided with a plurality of Coriolis masses as an integral portion and constitute a three-axis MEMS gyro sensor element capable of detecting angular velocity in directions along three mutually orthogonal axes.

In addition, the functional element 20 may constitute a detection unit on which an acceleration sensor that detects acceleration in each of mutually orthogonal three axis directions and outputs an acceleration signal according to the magnitude and direction of the detected three-axis acceleration, and an angular velocity sensor that detects angular velocity in each of mutually orthogonal three axis directions and outputs an angular velocity signal according to the magnitude and direction of the detected three-axis angular velocity are mounted.

### 1.2.2. Physical Quantity Sensor Elements

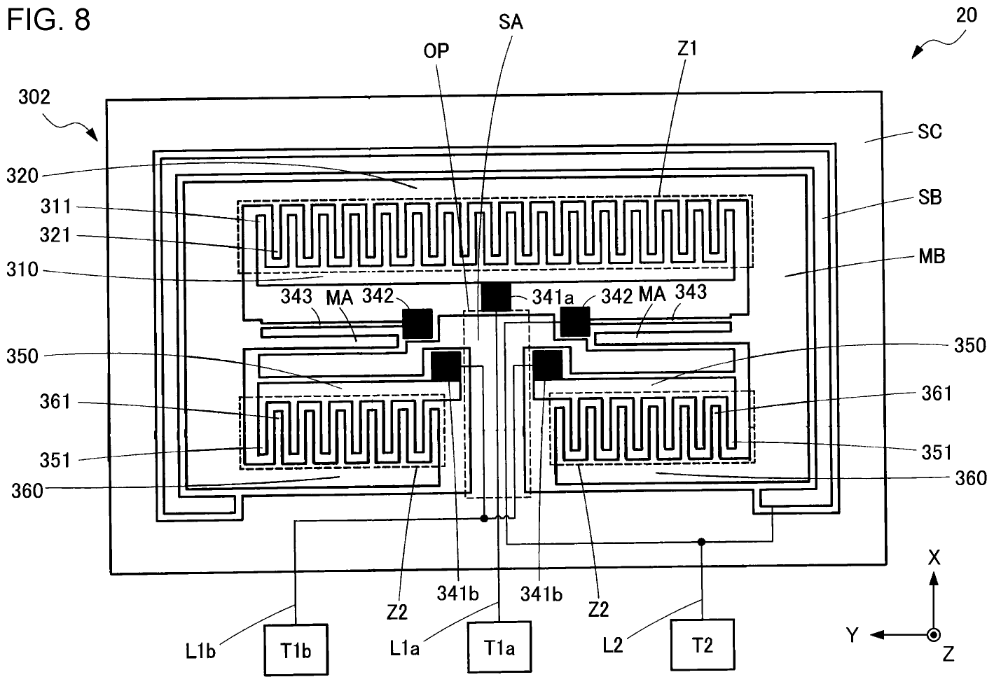

FIG. 8 is a plan view schematically showing an example of the functional element 20. The acceleration sensor element serving as the functional element 20 is a MEMS acceleration sensor element that detects acceleration along the Z-axis. As shown in FIG. 8, the functional element 20 includes a base substrate 302, fixed electrode sections 310 and 350, a movable body MB, fixed electrode fixing sections 341a and 341b, a wiring structure SA, and first wirings L1a and L1b. The fixed electrode section 310 has a plurality of fixed electrodes 311, and the fixed electrode section 350 has a plurality of fixed electrodes 351. The movable body MB includes movable electrode sections 320 and 360. The movable electrode section 320 of the movable body MB includes a movable electrode 321, and the movable electrode section 360 includes a movable electrode 361.

The base substrate 302 is, for example, a silicon substrate made of semiconductor silicon, or a glass substrate made of a glass material such as borosilicate glass. The base substrate 302 may be, for example, a silicon on insulator (SOI) substrate, in which an insulating layer is provided on a silicon substrate, and a structural layer made of a silicon material or the like is provided on the insulating layer.

The movable body MB moves relative to the base substrate 302 in accordance with acceleration or the like applied from the outside to the functional element 20. The functional element 20 can include a support beam 343 and a fixing section 342, and the movable body MB is coupled to the base substrate 302 through the support beam 343 and the fixing section 342. The support beam 343 is, for example, a torsion spring. The fixing section 342 is coupled to the base substrate 302 through an insulating film. The support beam 343 has one end coupled to the fixing section 342 and the other end coupled to the movable body MB.

The fixing section 342 is electrically coupled to the movable body MB through the support beam 343. In this way, the support beam 343 can twist in accordance with acceleration or the like applied from the outside, thereby allowing the movable body MB to perform a seesaw motion relative to the base substrate 302.

A cavity is provided on the −Z direction side of the movable body MB. The cavity is a space formed by a portion of the base substrate 302 being recessed in the −Z direction. A cavity provided in the base substrate 302 allows the movable body MB to perform a seesaw motion without coming into contact with the base substrate 302. Note that the movable body MB does not have to be directly coupled to the base substrate 302.

The fixed electrode sections 310 and 350, together with the movable electrode sections 320 and 360 of the movable body MB, are responsible for detecting acceleration in the functional element 20. The fixed electrode sections 310 and 350 are fixed to the base substrate 302. The plurality of fixed electrodes 311 of the fixed electrode section 310 are provided to face the plurality of movable electrodes 321 of the movable electrode section 320. The plurality of fixed electrodes 351 of the fixed electrode section 350 are provided to face the plurality of movable electrodes 361 of the movable electrode section 360. The fixed electrode 311, the movable electrode 321, the fixed electrode 351, and the movable electrode 361 are each in a plate shape, and the electrodes are disposed to face each other. The fixed electrode 311 and the movable electrode 321, and the fixed electrode 351 and the movable electrode 361, function as probes, respectively, thereby detecting physical quantities such as acceleration.

In the following description, the fixed electrodes 311 and 351 and the movable electrodes 321 and 361 will be collectively referred to as probe electrodes as appropriate. An area where the fixed electrode 311 and the movable electrode 321 face each other to form a probe is called a detector Z1, and an area where the fixed electrode 351 and the movable electrode 361 face each other to form a probe is called a detector Z2.

The fixed electrode fixing section 341a fixes the fixed electrode section 310 to the base substrate 302, and the fixed electrode fixing section 341b fixes the fixed electrode section 350 to the base substrate 302. The fixed electrode fixing section 341a has one end coupled to the base substrate 302, and the other end coupled to the fixed electrode section 310. In addition, the fixed electrode fixing section 341b has one end coupled to the base substrate 302 and the other end coupled to the fixed electrode section 350. The fixed electrode fixing section 341a is also electrically coupled to the fixed electrode section 310, and the fixed electrode fixing section 341b is also electrically coupled to the fixed electrode section 350.

The functional element 20 may include a stopper structure SB and a shield structure SC. The stopper structure SB suppresses excessive movement of the movable body MB. For example, when the movable body MB is displaced excessively, excessive displacement is suppressed by hitting the stopper structure SB.

The shield structure SC electrically insulates the movable body MB and the stopper structure SB from the outside. The shield structure SC is configured to further surround the periphery of the stopper structure SB that surrounds the movable body MB in a plan view. The shield structure SC is set to, for example, ground potential. By setting the shield structure SC to ground potential, external electrical and magnetic influences can be suppressed, the movable body MB and the stopper structure SB inside the shield structure SC are maintained in an electrically and magnetically stable state, and highly accurate detection of physical quantities is possible at the detectors Z1 and Z2. The shield structure SC and the stopper structure SB can be made of a conductive material such as silicon doped with impurities, for example.

The first wirings L1a and L1b transmit detection signals of the fixed electrode sections 310 and 350 to fixed electrode terminals T1a and T1b, respectively. The first wiring L1a has one end coupled to the fixed electrode fixing section 341a, and the other end coupled to the fixed electrode terminal T1a. The first wiring L1a transmits a signal detected by the fixed electrode section 310 of the detector Z1 to the fixed electrode terminal T1a. The first wiring L1b has one end coupled to the fixed electrode fixing section 341b, and the other end coupled to the fixed electrode terminal T1b. The first wiring L1b transmits a signal detected by the fixed electrode section 350 of the detector Z2 to the fixed electrode terminal T1b. In the following description, the first wirings L1a and Lib will be collectively referred to as the first wiring L1 as appropriate.

The functional element 20 may include a second wiring L2 and a movable electrode terminal T2. The second wiring L2 electrically couples the fixing section 342 and the movable electrode terminal T2. The fixing section 342 serves as an anchor for the movable body MB, and is electrically coupled to the movable body MB. The movable body MB includes the movable electrodes 321 and 361 of the movable electrode sections 320 and 360. Therefore, the movable electrodes 321 and 361 of the movable electrode sections 320 and 360 are electrically coupled to the movable electrode terminal T2 through the second wiring L2.

The functional element 20 includes the fixing section 342 electrically coupled to the movable body MB, and the second wiring L2 having one end coupled to the fixing section 342. The second wiring L2 is wired on the wiring structure SA through an insulating film, and passes through an opening OP of the movable body MB to be drawn out to the outside of the movable body MB. In this way, the voltage of the movable electrodes 321 and 361 of the movable body MB can be controlled by the voltage applied to the movable electrode terminal T2.

The wiring structure SA is a structure provided in the opening OP of the movable body MB. The opening OP is a region that opens from near the center of the movable body MB to the outer side of the movable body MB in a plan view. The wiring structure SA is provided at least in the opening OP in a plan view. The wiring structure SA, similarly to the stopper structure SB and the shield structure SC, can be made of a conductive material such as silicon doped with impurities, for example.

The operation of the functional element 20 will be described. The initial state is a stationary state, and the movable electrode 321 provided on the detector Z1 and the movable electrode 361 provided on the detector Z2 are stationary at the same height relative to the base substrate 302. At this time, the facing area between the fixed electrode 311 and the movable electrode 321 in the detector Z1 is equal to the facing area between the fixed electrode 351 and the movable electrode 361 in the detector Z2.

When the acceleration is applied in the +Z direction, the movable electrode 321, which has a large rotation sensitivity, receives an inertial force in the direction opposite to the acceleration and is displaced in the −Z direction. The movable electrode 361 is displaced in the +Z direction, which is the opposite direction to the movable electrode 321. In this case, the facing area between the fixed electrode 311 and the movable electrode 321 at the detector Z1 is maintained substantially constant, while the facing area between the fixed electrode 351 and the movable electrode 361 at the detector Z2 decreases. On the other hand, when the acceleration is applied in the −Z direction, the movable electrode 321, which has a larger moment of inertia, receives an inertial force in the +Z direction and is displaced in the +Z direction, and the movable electrode 361 is displaced in the same direction as the acceleration, and thus the facing area of the probe electrodes at detector Z1 decreases and the facing area of the probe electrodes at detector Z2 is maintained substantially constant. In this way, regardless of whether the acceleration in the +Z direction or the −Z direction occurs to the functional element 20, a change in the facing area occurs in either the detector Z1 or Z2. In the functional element 20, this change in the facing area can be detected as a change in capacitance.

The fixed electrode 311 of the detector Z1 is coupled to the fixed electrode terminal T1a through the first wiring L1a, and the movable electrode 321 of the detector Z1 is coupled to the movable electrode terminal T2 through the second wiring L2. The fixed electrode 351 of the detector Z2 is coupled to the fixed electrode terminal T1b through the first wiring L1b, and the movable electrode 361 of the detector Z2 is coupled to the movable electrode terminal T2 through the second wiring L2. Therefore, the capacitance at the detector Z1 and the capacitance at the detector Z2 can be detected from the fixed electrode terminals T1a and T1b and the movable electrode terminal T2.

### 1.2.3. Vibration Element

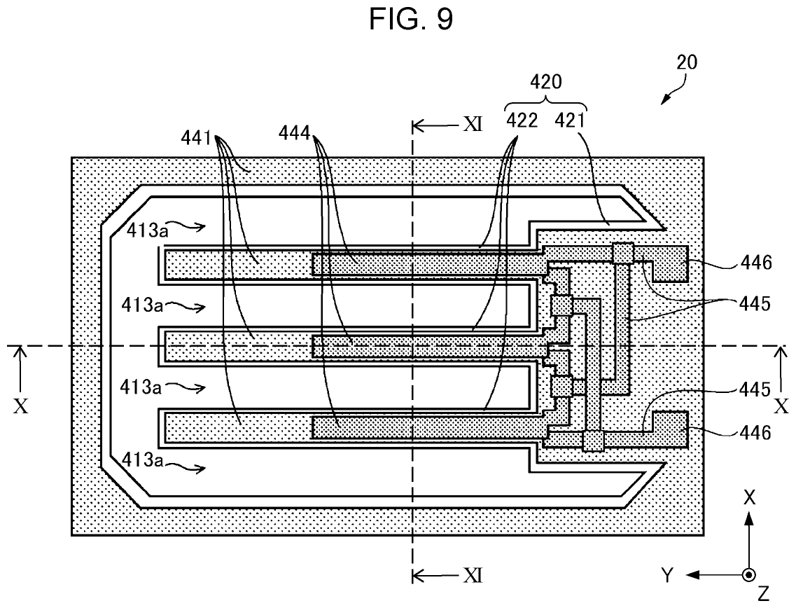

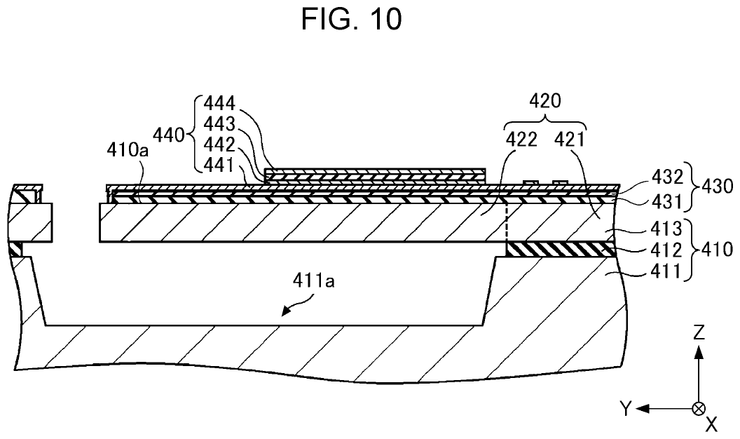

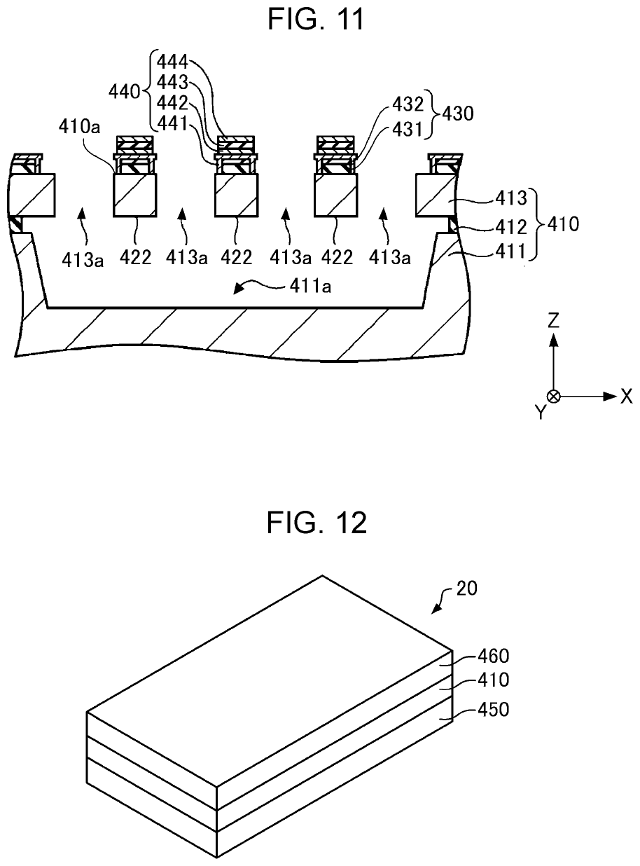

FIG. 9 is a schematic plan view showing an example of the functional element 20. FIG. 10 is a schematic cross-sectional view taken along line X-X in FIG. 9, and FIG. 11 is a schematic cross-sectional view taken along line XI-XI in FIG. 9. Here, the lines indicating the background of the cross section are omitted. The functional element 20 is a MEMS vibration element.

The MEMS vibration element serving as the functional element 20 can be manufactured by processing a silicon on insulator (SOI) substrate 410. The SOI substrate 410 is a substrate in which a base layer (silicon substrate 411), a buried oxide film (BOX) 412, and a surface silicon layer 413 are stacked in this order. For example, the silicon substrate 411 and the surface silicon layer 413 are made of single crystal silicon, and the buried oxide film 412 is made of a silicon oxide layer (SiO₂ or the like).

The functional element 20 includes a silicon substrate 411, a buried oxide film 412 disposed in a partial region of the silicon substrate 411, a vibration body 420 made of silicon of a surface silicon layer 413, a temperature characteristic adjustment film 430 which is a silicon oxide layer disposed in a predetermined region of the vibration body 420, and a piezoelectric driver 440 which is disposed on the opposite side of the temperature characteristic adjustment film 430 from the vibration body 420 and covers at least a portion of the temperature characteristic adjustment film 430.

The vibration body 420 has a fixing section 421 supported by the buried oxide film 412, and a vibrating arm 422 separated from the surrounding silicon other than the fixing section 421 by a groove (trench) 413a on the region where the buried oxide film 412 has been removed. In the shown example, the vibration body 420 has three vibrating arms 422. A cavity 411a is formed in the silicon substrate 411 at a position facing the vibrating arm 422.

The temperature characteristic adjustment film 430 is configured with a first silicon oxide (SiO₂) layer 431 and a second silicon oxide (SiO₂) layer 432, and the first silicon oxide layer 431 and the second silicon oxide layer 432 are stacked in this order from the surface silicon layer 413 side. The vibrating arms 422 vibrate in a direction intersecting a surface passing through the three vibrating arms 422. Therefore, the first surface 410a of the surface silicon layer 413 is a surface that intersects the vibration direction of the vibrating arm 422.

The first silicon oxide layer 431 is formed by thermally oxidizing the surface silicon layer 413 by a thermal oxidation method, and the second silicon oxide layer 432 is formed by a chemical vapor deposition (CVD) method or a sputtering method.

The piezoelectric driver 440 includes a polysilicon film 441, a first electrode 442, a piezoelectric layer 443, a second electrode 444, and a plurality of wirings 445. Note that the polysilicon film 441 is made of polysilicon not doped with impurities, and may be made of, for example, amorphous silicon. The polysilicon film 441 and the vibration body 420 cover the temperature characteristic adjustment film 430. Accordingly, the polysilicon film 441 can protect the temperature characteristic adjustment film 430 from etching of the silicon oxide layer around the piezoelectric driver 440.

The first electrode 442 and the second electrode 444 are disposed to sandwich the piezoelectric layer 443 therebetween. In the shown example, three sets of first electrodes 442, piezoelectric layers 443, and second electrodes 444 are provided corresponding to the three vibrating arms 422.

The plurality of wirings 445 are electrically coupled to the first electrode 442 and the second electrode 444 to vibrate the adjacent vibrating arms 422 in opposite phases. Furthermore, the plurality of wirings 445 are electrically coupled to electrode pads 446, and by applying a voltage between the two electrode pads 446 from the outside, the adjacent vibrating arms 422 can be vibrated in opposite phases.

As for the materials constituting these, for example, the piezoelectric layer 443 is made of aluminum nitride (AlN) or the like, the first electrode 442 and the second electrode 444 are made of titanium nitride (TiN) or the like, and the plurality of wirings 445 and the electrode pads 446 are made of aluminum (Al) or copper (Cu) or the like.

When a voltage is applied between the first electrode 442 and the second electrode 444 through the two electrode pads 446, the piezoelectric layer 443 expands and contracts accordingly, causing the vibrating arm 422 to vibrate. The vibration is excited strongly at a natural resonant frequency, and the impedance is at a minimum. As a result, an oscillator using a vibration element serving as the functional element 20 oscillates at an oscillation frequency determined mainly by the resonant frequency of the vibrating arm 422.

FIG. 12 is a perspective view schematically showing an example of the functional element 20.

As shown in FIG. 12, the functional element 20 may include a lower lid 450 and an upper lid 460. By sandwiching the SOI substrate 410 between the lower lid 450 and the upper lid 460, a vibration element formed at the SOI substrate 410 can be accommodated in the space created by the lower lid 450 and the upper lid 460. The lower lid 450 and the upper lid 460 are formed using a silicon substrate, for example.

Note that the vibration element serving as the functional element 20 is not limited to a vibration element using an out-plane bending vibration mode. For example, the vibration element may use an expansion vibration mode, a thickness extension vibration mode, a Lamb wave vibration mode, an in-plane bending vibration mode, or a surface wave vibration mode. The vibration element serving as the functional element 20 may be used, for example, as a timing device, an RF filter, a duplexer, an ultrasonic transducer, or the like. Further, the vibration element serving as the functional element 20 may be used as a piezoelectric mirror having an actuator function, a piezoelectric microphone having a pressure sensor function, an ultrasonic vibration sensor, or the like. Furthermore, the vibration element serving as the functional element 20 may be used as an electrostatic MEMS element, an electromagnetically driven MEMS element, a piezo-resistive MEMS element, or the like.

### 1.3. Coupling Section

### 1.3.1 Metal Bumps

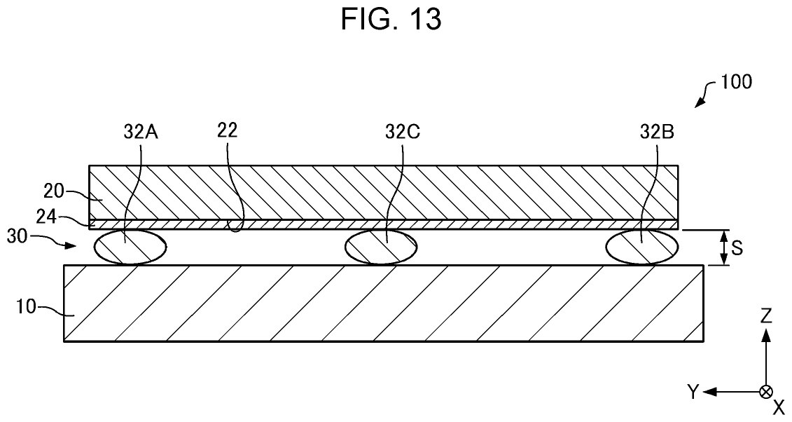

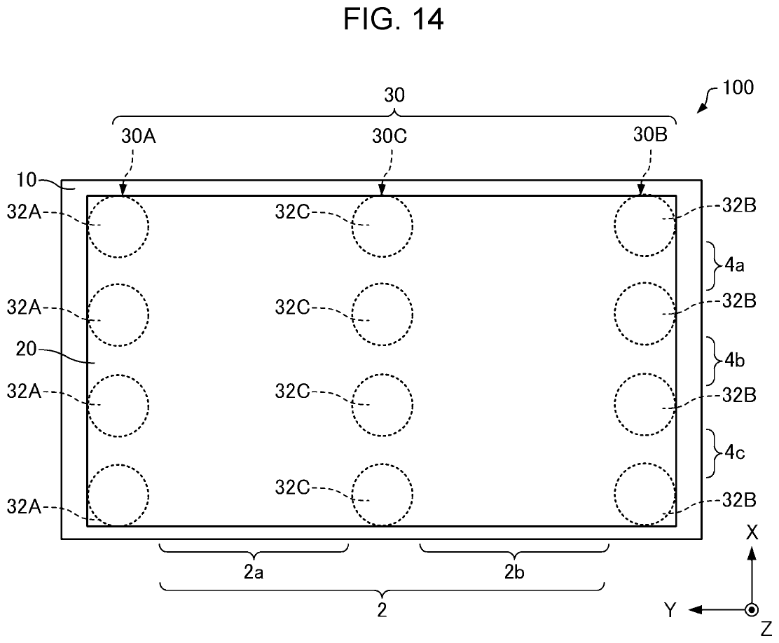

FIG. 13 is a cross-sectional view schematically showing an example of the electronic structure 100. FIG. 14 is a plan view schematically showing an example of the electronic structure 100. FIG. 13 is a cross-sectional view taken along line I-I of FIG. 14.

As shown in FIGS. 13 and 14, the first protrusion 32A, the second protrusion 32B, and the third protrusion 32C are metal bumps. The first protrusion 32A, the second protrusion 32B, and the third protrusion 32C support the functional element 20 and electrically couple the IC 10 and the functional element 20 to each other. Examples of the metal bumps include gold bumps and solder bumps.

A conductive layer 24 is formed at a bottom surface 22 of the functional element 20 on the IC 10 side. The bottom surface 22 of the functional element 20 is a surface facing the −Z direction. The conductive layer 24 is made of a material such as gold or aluminum, for example. The first protrusion 32A, the second protrusion 32B, and the third protrusion 32C are coupled to the conductive layer 24. The conductive layer 24 may function as, for example, an external electrode of the functional element 20. The conductive layer 24 is electrically coupled to the functional element 20 through the first protrusion 32A, the second protrusion 32B, and the third protrusion 32C.

Note that any one of the plurality of first protrusions 32A, the plurality of second protrusions 32B, and the plurality of third protrusions 32C may electrically couple the IC 10 and the functional element 20.

### 1.3.2 Metal Bumps

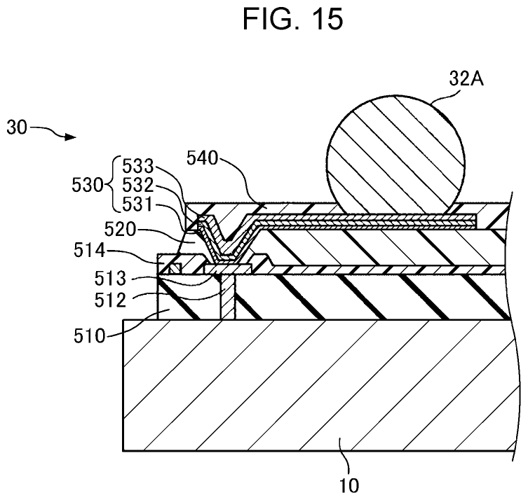

FIG. 15 is a diagram illustrating the coupling section 30. For convenience, the functional element 20 is omitted from FIG. 15.

As shown in FIG. 15, the coupling section 30 of the electronic structure 100 includes an interlayer insulating film 510, a stress relieving layer 520, a wiring 530, and an overcoat resin layer 540. The first protrusion 32A is a solder terminal.

A wiring layer including a plurality of wirings is disposed on the interlayer insulating film 510. A portion of these wirings constitutes a pad 513. The pad 513 is electrically coupled to the IC 10 through a contact via 512. A passivation film 514 having an opening at a position corresponding to the pad 513 is disposed on the wiring layer.

The stress relieving layer 520 is disposed on the passivation film 514 and has an opening at a position corresponding to the pad 513. The material of the stress relieving layer 520 is, for example, a polyimide resin, a silicone modified polyimide resin, an epoxy resin, a silicone modified epoxy resin, or the like.

The wiring 530 includes, for example, a first seed layer 531 of titanium tungsten (TiW) or the like, a second seed layer 532 of copper (Cu), and a copper plating layer 533 disposed in this order on the stress relieving layer 520. The wiring 530 is electrically coupled to the IC 10 through the pad 513 and the like.

The overcoat resin layer 540 is disposed on the stress relieving layer 520 on which the wiring 530 is disposed, and has openings at positions corresponding to the plurality of lands. As the overcoat resin layer 540, for example, a solder resist made of a photosensitive phenolic resin or the like is used.

The first protrusion 32A is, for example, a solder ball. The first protrusion 32A is electrically coupled to the wiring 530. The first protrusion 32A is electrically coupled to the IC 10 through the wiring 530. In the electronic structure 100, the IC 10 and the functional element 20 are electrically coupled through the first protrusion 32A.

Here, the first protrusion 32A has been described, but the second protrusion 32B and the third protrusion 32C have the same configuration, and thus description thereof will be omitted.

### 1.3.3. Bonding Section

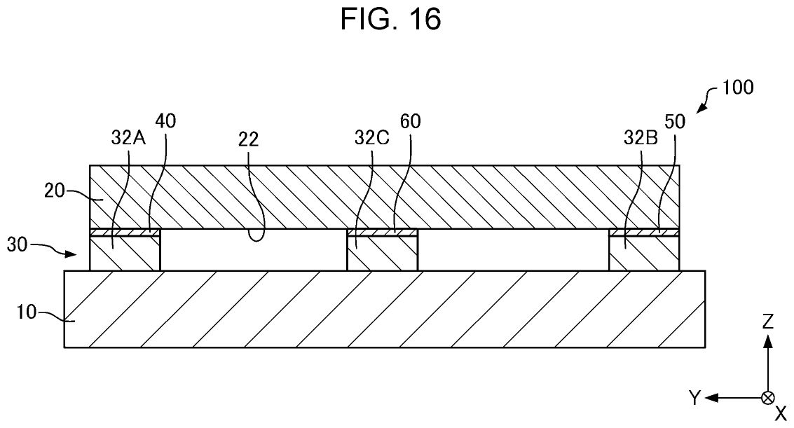

FIG. 16 is a cross-sectional view schematically showing an example of the electronic structure 100. As shown in FIG. 16, the electronic structure 100 includes a bonding section 40 (an example of a first bonding section), a bonding section 50, and a bonding section 60 (an example of a second bonding section).

FIG. 17 is a cross-sectional view schematically showing the bonding section 40.

The bonding section 40 bonds the bottom surface 22 of the functional element 20 on the circuit element 10 side to the first protrusion 32A. The bottom surface 22 of the functional element 20 may be, for example, a bottom surface of the base substrate 212 of the functional element 20 shown in FIG. 6, a bottom surface of the base substrate 302 shown in FIG. 8, or a bottom surface of the silicon substrate 411 of the functional element 20 shown in FIG. 10. The bottom surface 22 of the functional element 20 may be covered with a silicon oxide film.

The bonding section 40 includes a eutectic layer 610 (an example of a first eutectic layer) having, as a main component, a eutectic alloy of a first metal having aluminum as a main component, a second metal having germanium or silicon, and a third metal having titanium or nickel. The bonding section 40 includes a eutectic layer 610 having, as a main component, a eutectic alloy of a first metal layer 612 having aluminum as a main component, a second metal layer 614 having germanium or silicon, and a third metal layer 616 having titanium or nickel. The first metal layer 612, the second metal layer 614, and the third metal layer 616 are stacked in this order from the first protrusion 32A side. In the shown example, the first metal layer 612, the second metal layer 614, and the third metal layer 616 are each depicted as an independent layer, but their interfaces are eutectic-bonded. By including the eutectic layer 610 in the bonding section 40, the formation of an interface between different materials in the bonding section 40 can be suppressed. Therefore, by using the bonding section 40 to bond the functional element 20 to the first protrusion 32A, the bonding strength can be improved.

Although not shown, the eutectic layer 610 may further include a fourth metal layer between the first protrusion 32A and the first metal layer 612, the fourth metal layer having titanium as a main component.

The bonding section 50 bonds the bottom surface 22 of the functional element 20 to the second protrusion 32B. The configuration of the bonding section 50 is similar to the configuration of the bonding section 40 shown in FIG. 17. Therefore, by bonding the functional element 20 and the second protrusion 32B at the bonding section 50, the bonding strength can be improved.

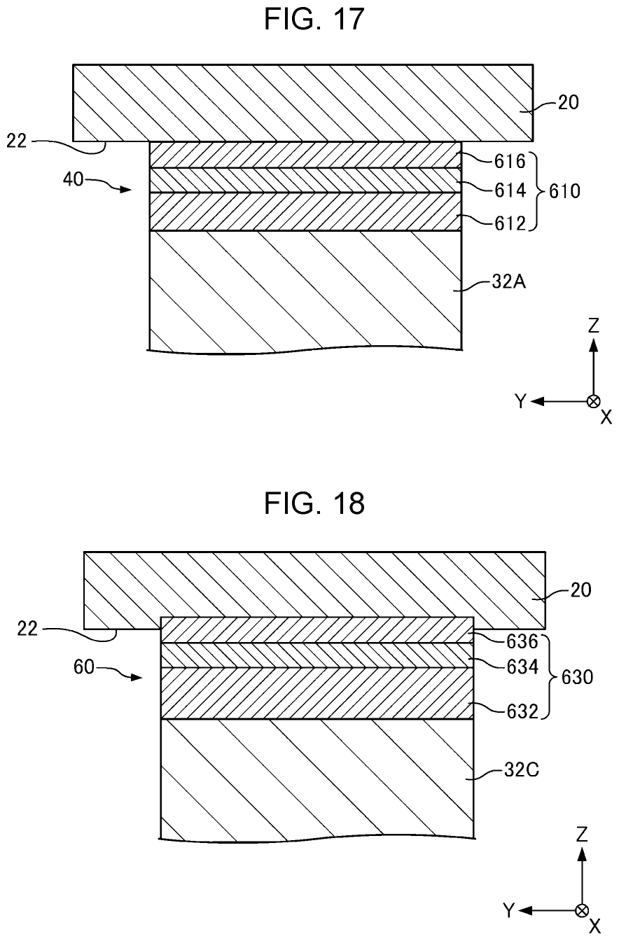

FIG. 18 is a cross-sectional view schematically showing the bonding section 60.

The bonding section 60 bonds the bottom surface 22 of the functional element 20 to the third protrusion 32C. Furthermore, the bonding section 60 is electrically coupled to the functional element 20.

The bonding section 60 includes a eutectic layer 630 (an example of a second eutectic layer) that diffuses into the inside of the base substrate of the functional element 20 and is electrically coupled to the base substrate. The base substrate may be, for example, the base substrate 212 of the functional element 20 shown in FIG. 6, the base substrate 302 shown in FIG. 8, or the silicon substrate 411 of the functional element 20 shown in FIG. 10.

The bonding section 60 includes a eutectic layer 630 having, as a main component, a eutectic alloy of a first metal having aluminum as a main component, a second metal having germanium as a main component, and a third metal having titanium as a main component. The bonding section 60 includes a eutectic layer 630 having, as a main component, a eutectic alloy of a first metal layer 632 having aluminum as a main component, a second metal layer 634 having germanium as a main component, and a third metal layer 636 having titanium as a main component. The first metal layer 632, the second metal layer 634, and the third metal layer 636 are stacked in this order from the third protrusion 32C side.

The first metal layer 632 is provided on the third protrusion 32C. The third metal layer 636 is provided on a base substrate of the functional element 20 made of silicon, and is electrically coupled to the base substrate. The second metal layer 634 is provided between the third metal layer 636 and the first metal layer 632. In the shown example, the first metal layer 632, the second metal layer 634, and the third metal layer 636 are each depicted as an independent layer, but their interfaces are eutectic-bonded. The eutectic layer 630 is a eutectic reaction layer having an AlGeTi alloy as a main component.

In the example shown in FIG. 18, the third metal layer 636 is shown as diffusing into the inside of the base substrate, but the first metal layer 632, the second metal layer 634, and an AlGeTi alloy layer generated by the eutectic reaction of the third metal layer 636 are actually diffusing into the inside of the base substrate. That is, the aluminum component is diffused into the inside of the base substrate. In this manner, the bonding section 60 is electrically coupled to the base substrate. Therefore, for example, the base substrate can be grounded using the bonding section 60.

In the above, the case where the bonding section 60 is provided between the functional element 20 and the third protrusion 32C has been described, but the bonding section 60 may also be provided between the functional element 20 and the first protrusion 32A, or the bonding section 60 may be provided between the functional element 20 and the second protrusion 32B.

### 1.3.4. Disposition Examples of Protrusion

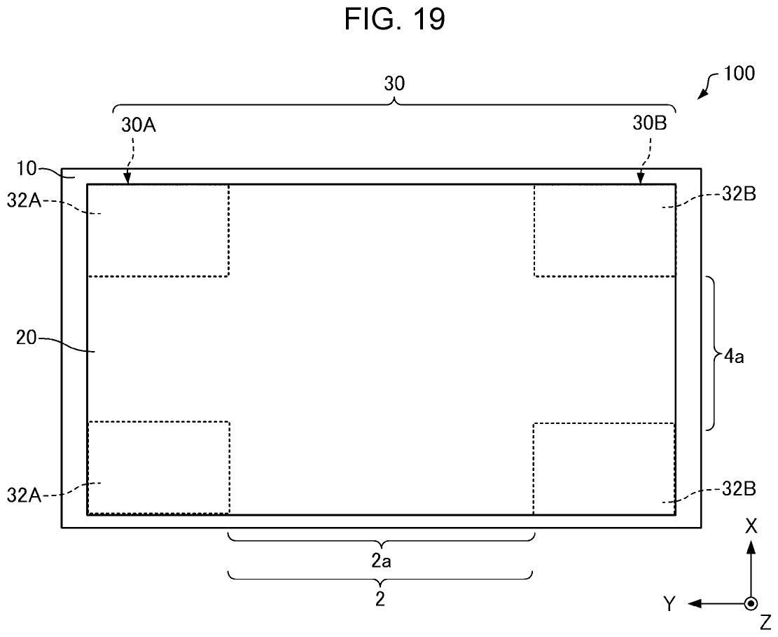

FIG. 19 is a plan view schematically showing an example of the electronic structure 100.

As shown in FIG. 19, the coupling section 30 may have the first protrusion group 30A and the second protrusion group 30B, but may not have the third protrusion group 30C. In the shown example, the number of first protrusions 32A constituting the first protrusion group 30A is two. Similarly, the number of second protrusions 32B constituting the second protrusion group 30B is two. In this case, the first space 2a and the space 4a are provided between the IC 10 and the functional element 20.

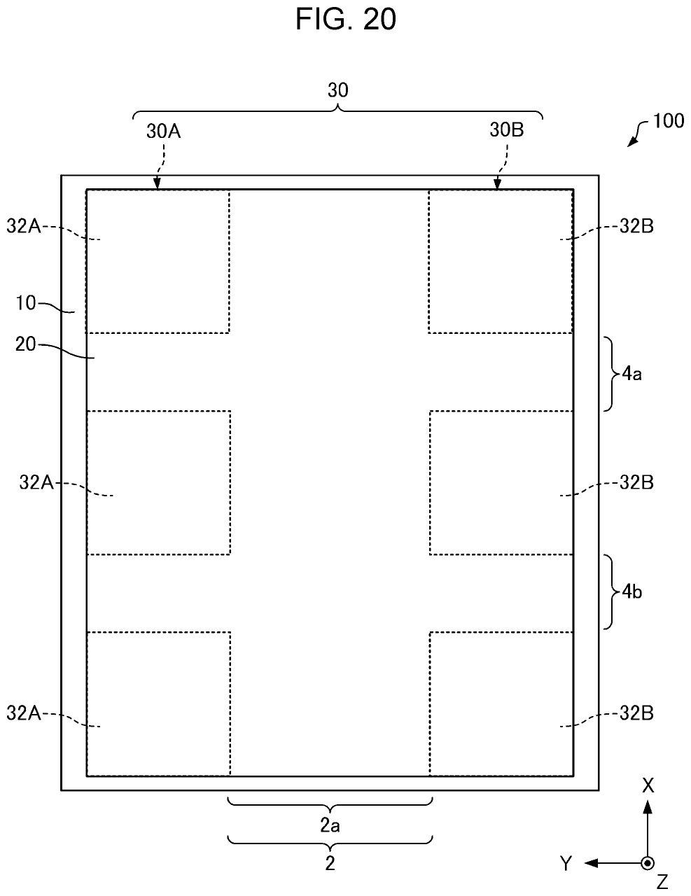

FIG. 20 is a plan view schematically showing an example of the electronic structure 100.

As shown in FIG. 20, the coupling section 30 may have the first protrusion group 30A and the second protrusion group 30B, but may not have the third protrusion group 30C. In the shown example, the number of first protrusions 32A constituting the first protrusion group 30A is three. Similarly, the number of second protrusions 32B constituting the second protrusion group 30B is three. In this case, the first space 2a, the space 4a, and the space 4b are provided between the IC 10 and the functional element 20.

In this way, the number of first protrusions 32A constituting the first protrusion group 30A and the number of second protrusions 32B constituting the second protrusion group 30B are not particularly limited as long as they are two or more. Moreover, the coupling section 30 may or may not have the third protrusion group 30C. In the examples shown in FIGS. 1 and 2, the coupling section 30 has three protrusion groups; however, although not shown, the coupling section 30 may have four or more protrusion groups.

### 1.4 Effect

The electronic structure 100 includes an IC 10 and a functional element 20 that is disposed at a position overlapping the IC 10 in a plan view in the Z-axis direction along the Z-axis. In addition, between the IC 10 and the functional element 20, there are provided a first protrusion group 30A including a plurality of first protrusions 32A disposed in the X-axis direction along the X-axis, and a second protrusion group 30B including a plurality of second protrusions 32B disposed in the X-axis direction. In addition, the IC 10 and the functional element 20 are coupled through the first protrusion group 30A and the second protrusion group 30B, and a gap 2 is provided between the first protrusion group 30A and the second protrusion group 30B, and the gap 2 includes the first space 2a that is provided from the end of the IC 10 on the negative side of the X-axis to the end of the IC 10 on the positive side of the X-axis.

In this way, the electronic structure 100 includes the first space 2a between the IC 10 and the functional element 20, which is provided from the end of the IC 10 on the negative side of the X-axis to the end of the IC 10 on the positive side of the X-axis, and therefore the flow of gas such as atmosphere can be promoted in the first space 2a, and the heat insulation effect between the IC 10 and the functional element 20 can be improved. Therefore, in the electronic structure 100, for example, when the functional element 20 is an angular velocity sensor element, it is possible to reduce temperature drift, which is the fluctuation in output due to temperature in a stationary state in which an angular velocity is not applied.

Furthermore, in the electronic structure 100, the IC 10 and the functional element 20 are coupled by the plurality of first protrusions 32A and the plurality of second protrusions 32B, and therefore the functional element 20 can be supported more stably than, for example, when the functional element 20 is supported in a cantilever manner or when the functional element 20 is supported by a single supporter. Accordingly, the electronic structure 100 can have, for example, improved resistance to vibration.

In the electronic structure 100, a third protrusion group 30C including a plurality of third protrusions 32C disposed in the X-axis direction in a plan view is provided between the first protrusion group 30A and the second protrusion group 30B, and the IC 10 and the functional element 20 are coupled through the third protrusion group 30C. Therefore, in the electronic structure 100, the bending of the functional element 20 can be reduced and the flatness of the functional element 20 can be improved, compared to when the functional element 20 is supported by two protrusion groups.

In the electronic structure 100, the first space 2a is provided between the first protrusion group 30A and the third protrusion group 30C. Therefore, in the electronic structure 100, the flow of gas can be promoted in the first space 2a, and the heat insulation effect between the IC 10 and the functional element 20 can be improved.

In the electronic structure 100, the second space 2b is provided between the second protrusion group 30B and the third protrusion group 30C, and the second space 2b is provided from the end of the IC 10 on the negative side of the X-axis to the end of the IC 10 on the positive side of the X-axis. Therefore, in the electronic structure 100, the flow of gas such as the atmosphere can be promoted in the first space 2a and the second space 2b, and the heat insulation effect between the IC 10 and the functional element 20 can be further improved.

In the electronic structure 100, when the interval between the IC 10 and the functional element 20 is denoted by S, 18 μm≤S is satisfied. Therefore, in the electronic structure 100, the flow of gas can be promoted in the first space 2a, and the heat insulation effect between the IC 10 and the functional element 20 can be improved.

In the electronic structure 100, 18 μm≤S≤70 μm is satisfied. Therefore, in the electronic structure 100, the flow of gas can be promoted in the first space 2a, and the heat insulation effect between the IC 10 and the functional element 20 can be improved.

In the electronic structure 100, when the interval between the first protrusion group 30A and the third protrusion group 30C is denoted by L1 and the width of the first protrusion group 30A is denoted by L2, 0.15<L2/L1<1.1 is satisfied. Therefore, in the electronic structure 100, it is possible to stably support the functional element 20 while ensuring the width of the first space 2a.

In the electronic structure 100, 0.25<L2/L1<0.85 is satisfied. Therefore, in the electronic structure 100, it is possible to stably support the functional element 20 while ensuring the width of the first space 2a.

The electronic structure 100 includes the bonding section 40 as a first bonding section that bonds the bottom surface 22 on the IC 10 side of the functional element 20 to the first protrusion 32A, and the bonding section 40 includes the eutectic layer 610 having, as a main component, a eutectic alloy of a first metal having aluminum as a main component, a second metal having germanium or silicon, and a third metal having titanium or nickel. Therefore, in the electronic structure 100, the bonding strength between the first protrusion 32A and the functional element 20 can be improved.

The electronic structure 100 includes the bonding section 60 as a second bonding section that bonds the bottom surface 22 on the IC 10 side of the functional element 20 to the third protrusion 32C, and the bonding section 60 includes the eutectic layer 630 that diffuses into the inside of the base substrate of the functional element 20 and is electrically coupled to the base substrate. In addition, the eutectic layer 630 has, as a main component, a eutectic alloy of a first metal having aluminum as a main component, a second metal having germanium as a main component, and a third metal having titanium as a main component. Therefore, in the electronic structure 100, the bonding section 60 can bond the functional element 20 and the third protrusion 32C, and the bonding section 60 and the base substrate can be electrically coupled.

In the electronic structure 100, the functional element 20 is any one of a MEMS sensor element, a MEMS vibration element, and a MEMS element. Therefore, in the electronic structure 100, the influence of the heat generated by the IC 10 on the functional element 20 can be reduced.

### 2. Second Embodiment

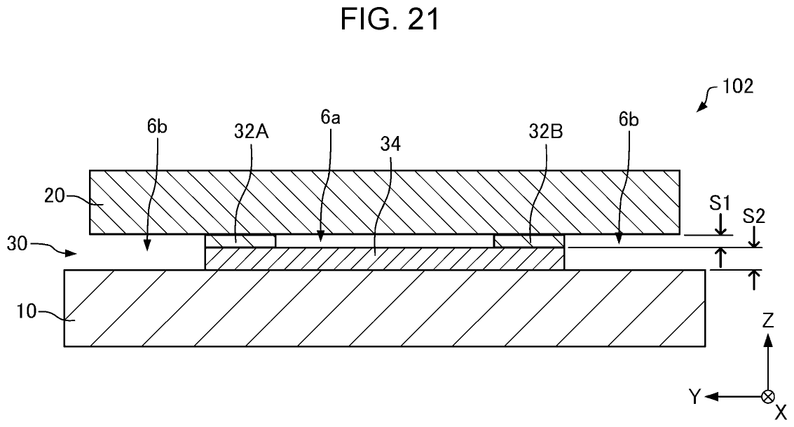

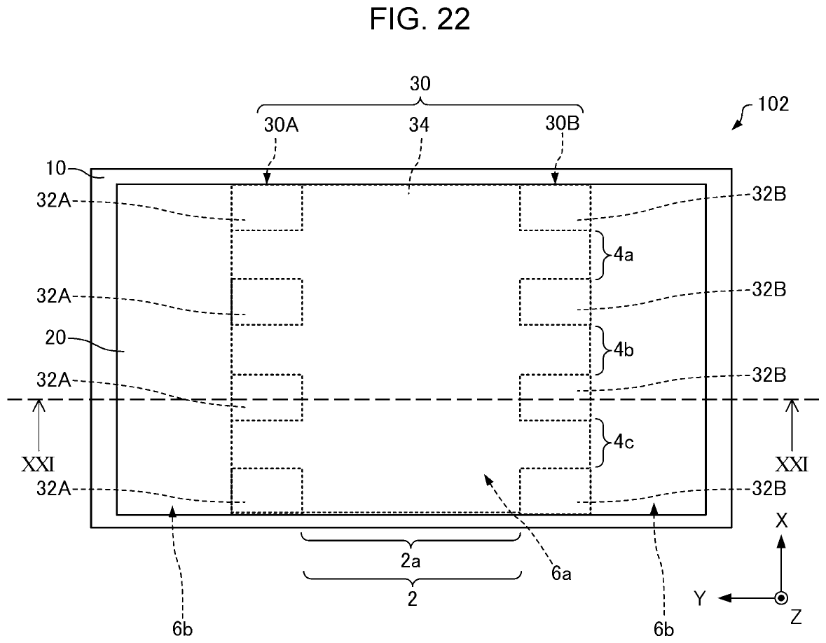

Next, an electronic structure according to a second embodiment will be described with reference to the drawings. FIG. 21 is a cross-sectional view showing an example of a configuration of an electronic structure 102 according to the second embodiment. FIG. 22 is a plan view showing an example of a configuration of the electronic structure 102 according to the second embodiment. FIG. 21 is a cross-sectional view taken along line XXI-XXI of FIG. 22. Hereinafter, in the electronic structure 102 according to the second embodiment, members having the same functions as the components of the electronic structure 100 according to the first embodiment described above will be denoted by the same reference numerals, and detailed description thereof will be omitted.

In the electronic structure 102, as shown in FIGS. 21 and 22, the coupling section 30 has a step 34. A first protrusion group 30A including a plurality of first protrusions 32A and a second protrusion group 30B including a plurality of second protrusions 32B are provided on the step 34. The thickness of the first protrusion 32A and the second protrusion 32B is denoted by S1, and the thickness of the step 34 is denoted by S2.

The step 34 is provided on the IC 10. On the IC 10, there are formed a region where the step 34 is provided and a region where the step 34 is not provided. Therefore, between the IC 10 and the functional element 20, a space 6a between the step 34 and the functional element 20, and a space 6b between the IC 10 and the functional element 20 are formed. In the shown example, the space 6a corresponds to the first space 2a. For example, when the coupling section 30 is formed of an insulating layer such as a silicon oxide film, the coupling section 30 having the step 34, the first protrusion group 30A, and the second protrusion group 30B can be formed by patterning the insulating layer by photolithography or the like.

The interval S1 between the step 34 and the functional element 20 is smaller than the interval (S1+S2) between the IC 10 and the functional element 20. That is, the height of the space 6a (that is, the thickness S1 of the first protrusion 32A and the second protrusion 32B) is smaller than the height of the space 6b. Here, the height is the size along the Z-axis. Due to the difference in height between the space 6a and the space 6b, the pressure in the space 6a becomes higher than the pressure in the space 6b. Accordingly, the gas can flow from the space 6a to the space 6b. Therefore, the flow of gas can be promoted in the first space 2a.

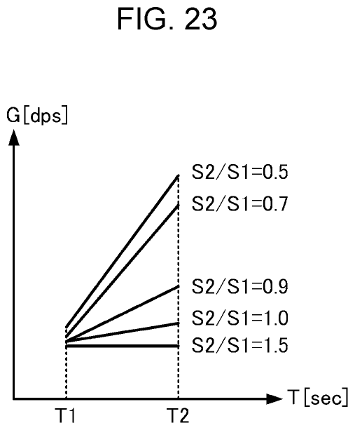

FIG. 23 is a graph showing a temperature change of an output signal of the electronic structure 102. In FIG. 23, the thickness of the first protrusion 32A and the second protrusion 32B is S1, and therefore the interval between the step 34 and the functional element 20 is S1. Here, focusing on the interval S1 between the step 34 and the functional element 20 and the thickness (height) S2 of the step 34, the temperature change of the output signal G of the electronic structure 102 is measured using the ratio of these, S2/S1, as a variable. Here, the functional element 20 is an angular velocity sensor element, and the change in the output signal G of the electronic structure 102 when the temperature of the functional element 20 rises at a constant rate between time T1 and time T2 is plotted. The output signal G is an output signal in a stationary state in which an angular velocity is not applied.

As shown in FIG. 23, when S2/S1>1 is satisfied, the change in the output signal G is small. Furthermore, when S2/S1>1.5 is satisfied, the change in the output signal G is smaller. From these results, it is considered that when S2/S1>1 is satisfied, the flow of gas can be promoted in the first space 2a, and the heat insulation effect between the IC 10 and the functional element 20 can be improved. Furthermore, when S2/S1>1.5 is satisfied, it is considered that the flow of gas can be promoted more effectively in the first space 2a, and the heat insulation effect between the IC 10 and the functional element 20 can be further improved.

Therefore, in the electronic structure 102, S2/S1>1 is satisfied, and preferably, S2/S1>1.5 is satisfied. Accordingly, the flow of gas can be promoted in the first space 2a, and the heat insulation effect between the IC 10 and the functional element 20 can be improved.

### 3. Third Embodiment

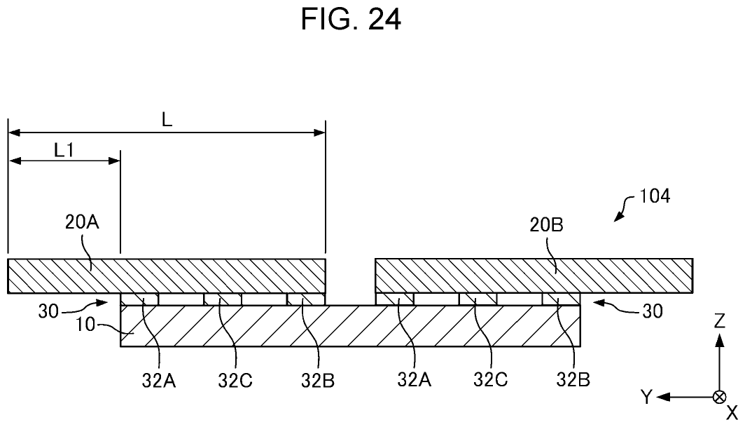

Next, an electronic structure according to a third embodiment will be described with reference to the drawings. FIG. 24 is a cross-sectional view showing an example of a configuration of an electronic structure 104 according to the third embodiment. Hereinafter, in the electronic structure 104 according to the third embodiment, members having the same functions as the components of the electronic structure 100 according to the first embodiment described above will be denoted by the same reference numerals, and detailed description thereof will be omitted.

In the electronic structure 104, two functional elements 20A and 20B are disposed on the IC 10. The functional element 20A protrudes from the IC 10 in the +Y direction. That is, a portion of the functional element 20A does not overlap the IC 10 in a plan view seen in the direction along the Z-axis. Therefore, the flow of gas can be promoted in an overhanging portion where the functional element 20A protrudes from the IC 10. Furthermore, since heat from the IC 10 is less likely to be transferred to the overhanging portion of the functional element 20A, the heat insulation effect between the IC 10 and the functional element 20A can be improved.

Similarly, the functional element 20B protrudes from the IC 10 in the −Y direction. That is, a portion of the functional element 20B does not overlap the IC 10 in a plan view seen in the direction along the Z-axis. Therefore, in the functional element 20B as well, the heat insulation effect between the IC 10 and the functional element 20B can be improved, similarly to the functional element 20A.

In a case where the functional element 20A protrudes from the IC 10 along the Y-axis, when the length of the functional element 20A along the Y-axis is denoted by L and the length of the overhanging portion of the functional element 20A is denoted by L1, 0.3<L1/L<1.0 is satisfied, and preferably 0.45<L1/L<0.65 is satisfied. Accordingly, the heat insulation effect between the IC 10 and the functional element 20A can be improved.

### 4. Fourth Embodiment

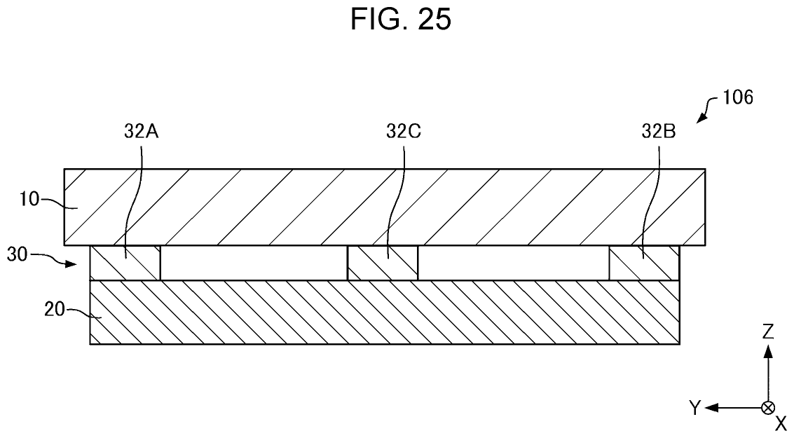

Next, an electronic structure according to a fourth embodiment will be described with reference to the drawings. FIG. 25 is a cross-sectional view showing an example of a configuration of an electronic structure 106 according to the fourth embodiment. Hereinafter, in the electronic structure 106 according to the fourth embodiment, members having the same functions as the components of the electronic structure 100 according to the first embodiment described above will be denoted by the same reference numerals, and detailed description thereof will be omitted.

In the electronic structure 100 shown in FIG. 1, the functional element 20 is disposed on the IC 10 through the coupling section 30, but as shown in FIG. 25, the IC 10 may be disposed on the functional element 20 through the coupling section 30.

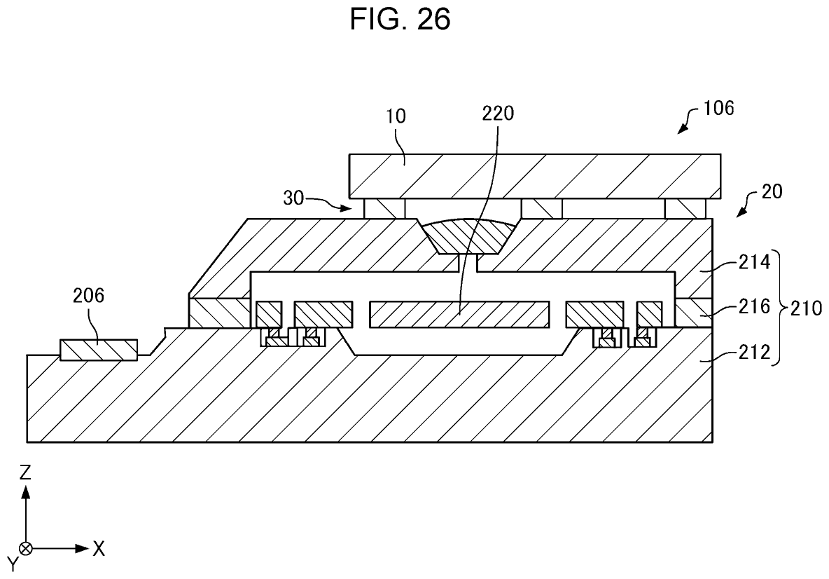

FIG. 26 is a diagram schematically showing an electronic structure 106 in a case where the functional element 20 is a physical quantity sensor element shown in FIG. 6. As shown in FIG. 26, the IC 10 is coupled to the cap 214 through the coupling section 30.

In the electronic structure 106 as well, similarly to the electronic structure 100, the heat insulation effect between the IC 10 and the functional element 20 can be improved.

### 5. Fifth Embodiment

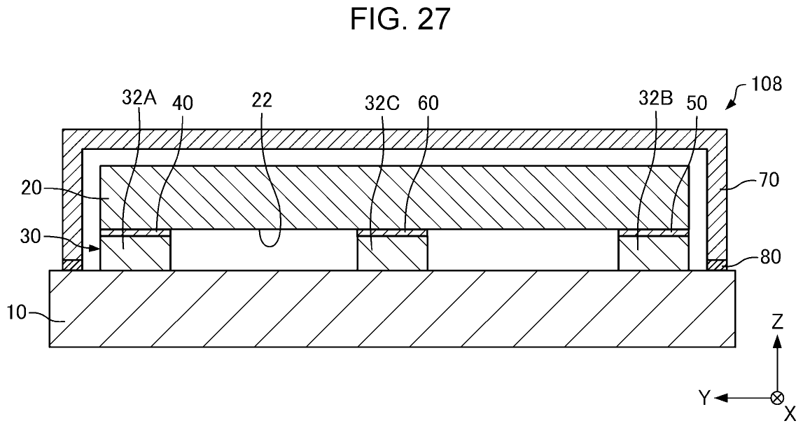

Next, an electronic structure according to a fifth embodiment will be described with reference to the drawings. FIG. 27 is a cross-sectional view showing an example of a configuration of an electronic structure 108 according to the fifth embodiment. Hereinafter, in the electronic structure 108 according to the fifth embodiment, members having the same functions as the components of the electronic structure 100 according to the first embodiment described above will be denoted by the same reference numerals, and detailed description thereof will be omitted.

The electronic structure 108 includes a lid 70. The lid 70 is bonded to the IC 10 by a bonding section 80. In the electronic structure 108, the functional element 20 can be accommodated in an internal space surrounded by the lid 70 and the IC 10. For example, the internal space is in a reduced pressure vacuum state or is filled with an inert gas such as nitrogen, helium, or argon. The bonding section 80 is used as a sealing material for sealing the functional element 20 with the IC 10 and the lid 70, and is disposed in a ring shape on the IC 10 to surround the functional element 20.

The lid 70 can be made of a metal such as Kovar or 42 alloy. The lid 70 can be made of ceramic insulating materials such as an aluminum oxide sintered body, a mullite sintered body, an aluminum nitride sintered body, a silicon carbide sintered body, a glass ceramic sintered body, or the like, which are formed by molding, stacking, and sintering ceramic green sheets, or quartz, glass, silicon (high resistance silicon), or the like.

The bonding section 80 may be formed using the eutectic layer 610 shown in FIG. 17 described above. Furthermore, the bonding section 80 may be formed using the eutectic layer 630 shown in FIG. 18 described above. The IC 10 and the lid 70 may be bonded by seam welding or with a bonding member such as low melting point glass or an adhesive.

In the shown example, the case has been described where the functional element 20 is accommodated in the internal space created by the IC 10 and the lid 70 in the electronic structure 100 shown in FIG. 27, but the functional element 20 may also be accommodated in the internal space created by the IC 10 and the lid 70 in the other electronic structures mentioned above in a similar manner.

Also, although not shown, the electronic structure 108 may be covered with a resin molding material. The resin molding material is not particularly limited, but an epoxy resin, for example can be used.

### 6. Sixth Embodiment

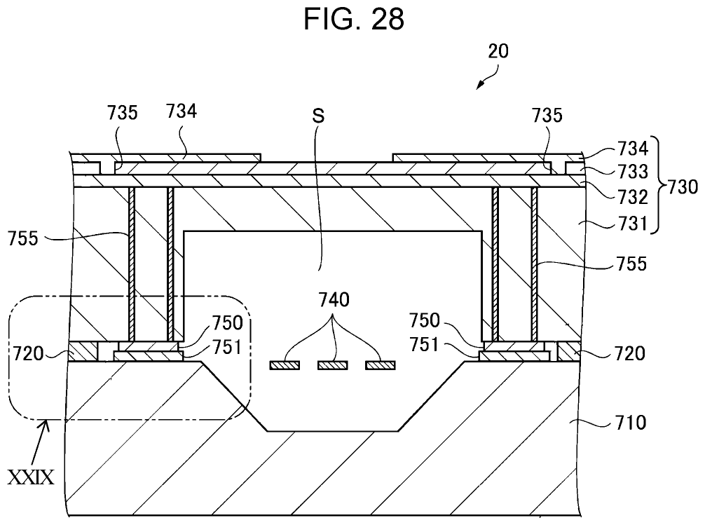

Next, an electronic structure according to a sixth embodiment will be described with reference to the drawings. FIG. 28 is a cross-sectional view showing an example of a configuration of a functional element 20 of an electronic structure according to the sixth embodiment. Hereinafter, in the functional element 20 of the electronic structure according to the sixth embodiment, members having the same functions as the components of the electronic structure 100 according to the first embodiment described above will be denoted by the same reference numerals, and detailed description thereof will be omitted.

The functional element 20 includes a base substrate 710, a first bonding material 720 and a second bonding material 750 disposed on the base substrate 710, and a lid 730 disposed on the first bonding material 720. Furthermore, the functional element 20 includes a vibration section 740, a coupling electrode 751, and a through electrode 755.

The base substrate 710 is made of a silicon substrate, for example. The base substrate 710 includes a silicon on insulator (SOI) substrate, and is formed integrally with the vibration section 740.

In the lid 730, in order from the base side, a lid body 731, an oscillation circuit 732 configured with a semiconductor substrate, a first insulating layer 733, and an external electrode 734 that provides electrical coupling to the outside are disposed.

The first bonding material 720 and the second bonding material 750 are disposed between the lid 730 and the base substrate 710. The first bonding material 720 is used as a sealing material for sealing the vibration section 740 by the base substrate 710 and the lid 730, and is disposed in a ring shape on the base substrate 710 to surround the vibration section 740. The second bonding material 750 is used as an electrode for electrically coupling the coupling electrode 751 to the lid 730, specifically, to the external electrode 734.

The configuration of the vibration section 740 is similar to that of the vibration element serving as the functional element 20 shown in, for example, FIGS. 9 to 11 described above, and therefore a description thereof will be omitted.

The through electrode 755 is electrically coupled to the external electrode 734 through the oscillation circuit 732 and a contact electrode 735 provided on the first insulating layer 733. Note that the functional element 20 may not have the oscillation circuit 732 and the through electrode 755 may be coupled to the external electrode 734 through the contact electrode 735. In this case, the oscillation circuit 732 may be mounted on the IC 10. The through electrode 755 is made of, for example, titanium (Ti), tungsten (W), copper (Cu), or the like.

A sealed space S is formed by the base substrate 710 and the lid 730, and the sealed space S accommodates the vibration section 740.

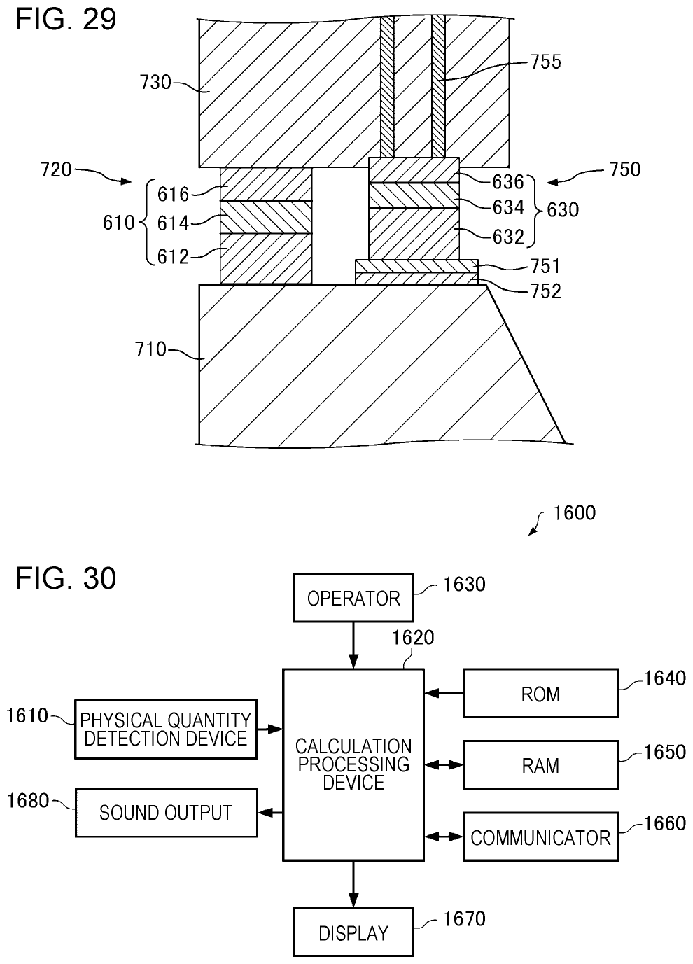

FIG. 29 is an enlarged cross-sectional view of a portion XXIX of the functional element 20 shown in FIG. 28. The first bonding material 720 is configured with a eutectic layer 610 having, as a main component, a eutectic alloy of a first metal layer 612 having aluminum as a main component, a second metal layer 614 having germanium or silicon, and a third metal layer 616 having titanium or nickel. Therefore, the bonding strength can be improved. The configuration of the first bonding material 720 is similar to that of the bonding section 40 shown in FIG. 17.

A second insulating layer 752 serving as an insulating layer is disposed between the coupling electrode 751 and the base substrate 710. The coupling electrode 751 is electrically coupled to the vibration section 740.

The second bonding material 750 is configured with a eutectic layer 630 having, as a main component, a eutectic alloy of a first metal layer 632 having aluminum as a main component, a second metal layer 634 having germanium as a main component, and a third metal layer 636 having titanium as a main component. Therefore, the second bonding material 750 can electrically couple the coupling electrode 751 and the through electrode 755. The configuration of the second bonding material 750 is similar to that of the bonding section 60 shown in FIG. 18.

### 7. Seventh Embodiment

### 7.1. Electronic Apparatus

Next, an electronic apparatus according to a seventh embodiment will be described with reference to the drawings. FIG. 30 is an example of a functional block diagram of an electronic apparatus according to the seventh embodiment. As shown in FIG. 30, an electronic apparatus 1600 includes a physical quantity detection device 1610, a calculation processing device 1620, an operator 1630, a ROM 1640, a RAM 1650, a communicator 1660, a display 1670, and a sound output 1680. Note that electronic apparatus 1600 may have some of the components shown in FIG. 30 omitted or modified, or other components added thereto.

The physical quantity detection device 1610 detects a physical quantity occurring on one axis or on a plurality of axes, and outputs a physical quantity signal to the calculation processing device 1620. As the physical quantity detection device 1610, the electronic structure according to each of the above-described embodiments or each of the modification examples can be applied.

The calculation processing device 1620 performs various calculation processes and control processes in accordance with programs stored in the ROM 1640 or the like. Specifically, the calculation processing device 1620 performs calculation processing such as various calculation processes and control processes based on a physical quantity signal output from the physical quantity detection device 1610. In addition, the calculation processing device 1620 performs various processes in response to operation signals from the operator 1630, a process of controlling the communicator 1660 to perform data communication with the outside, a process of transmitting display signals for displaying various types of information on the display 1670, a process of causing the sound output 1680 to output various sounds, and the like.

The operator 1630 is an input device including operation keys, button switches, or the like, and outputs an operation signal corresponding to an operation by a user to the calculation processing device 1620.

The ROM 1640 stores programs, data, and the like that are used by the calculation processing device 1620 to perform various calculation processes and control processes. The RAM 1650 is used as a work region for the calculation processing device 1620, and temporarily stores programs and data read from the ROM 1640, data input from the operator 1630, the results of calculations executed by the calculation processing device 1620 according to various programs, and the like.

The communicator 1660 performs various controls to establish data communication between the calculation processing device 1620 and an external device.

The display 1670 is a display device configured with a liquid crystal display (LCD), an organic electro-luminescence display (OELD), an electrophoretic display, or the like, and displays various types of information based on a display signal input from the calculation processing device 1620.

The sound output 1680 is a device that outputs sound, such as a speaker.

A variety of electronic apparatuses can be considered as the electronic apparatus 1600. Examples of electronic apparatuses include seismometers, work robots, health monitoring devices, unmanned driving devices, personal computers (for example, mobile personal computers, laptop personal computers, tablet personal computers), mobile terminals such as mobile phones, digital cameras, ink jet discharge devices such as ink jet printers, storage area network devices such as routers and switches, local area network devices, mobile terminal base station devices, televisions, video cameras, video recorders, car navigation devices, pagers, electronic organizers, electronic dictionaries, calculators, electronic game devices, game controllers, word processors, workstations, videophones, security television monitors, electronic binoculars, point of sale (POS) terminals, medical devices (for example, electronic thermometers, blood pressure monitors, blood glucose meters, electrocardiogram measuring devices, ultrasonic diagnostic devices, electronic endoscopes), fish finders, various measuring devices, instruments (for example, instruments for vehicles, aircraft, and ships), flight simulators, head-mounted displays, motion tracing, motion tracking, motion controllers, pedestrian position and orientation measurement (PDRs), head-up displays (HUDs), and the like.

### 7.2. Inertial Measurement Unit

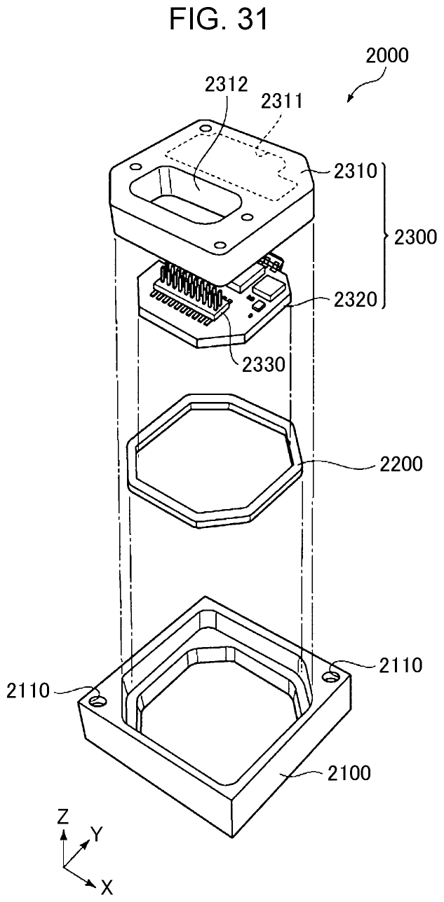

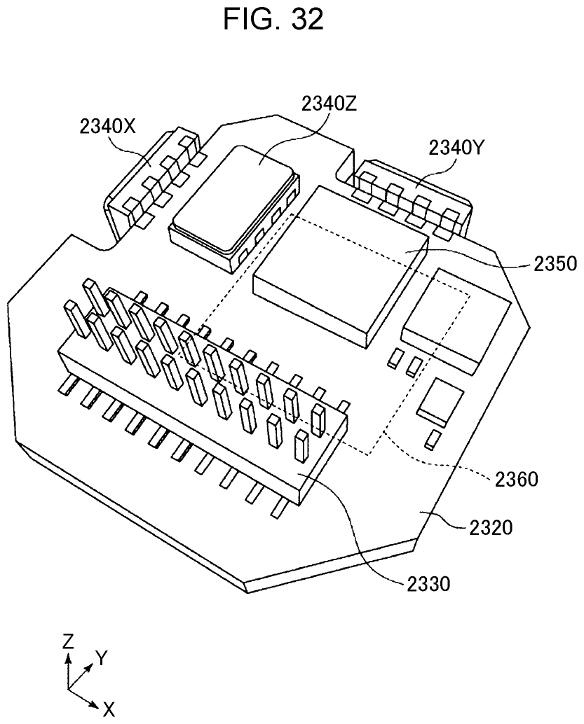

FIG. 31 is an exploded perspective view showing an embodiment of an inertial measurement unit as an example of the electronic apparatus according to the seventh embodiment. FIG. 32 is a perspective view of a substrate provided in the inertial measurement unit shown in FIG. 31. An inertial measurement unit (IMU) 2000 shown in FIG. 31 is a so-called six-axis motion sensor, and for example, is mounted on a moving object (object to be measured) such as an automobile, agricultural machinery such as a tractor, or a robot for use, and detects the attitude and behavior of the moving object. Further, the inertial measurement unit 2000 realizes highly accurate and stable automatic steering of a moving object. Furthermore, the inertial measurement unit 2000 is mounted on a gimbal that stabilizes an antenna mounted on a camera, a drone, or the like.

The inertial measurement unit 2000 includes an outer case 2100, a bonding member 2200, and a sensor module 2300, and the sensor module 2300 is fitted inside the outer case 2100 with the bonding member 2200 interposed therebetween.

The outer case 2100 is box-shaped, and screw holes 2110 for screwing into an object to be measured are provided at two diagonally opposite corners of the outer case 2100.

The sensor module 2300 includes an inner case 2310 and a substrate 2320, and is housed in the inside of the outer case 2100 described above with the inner case 2310 supporting the substrate 2320. Here, the inner case 2310 is bonded to the outer case 2100 through the bonding member 2200 with an adhesive or the like. In addition, the inner case 2310 has a recess 2311 that functions as a housing space for components mounted on the substrate 2320, and an opening 2312 for exposing a connector 2330 provided on the substrate 2320 to the outside. The substrate 2320 is, for example, a multilayer wiring substrate, and is bonded to the inner case 2310 with an adhesive or the like.

As shown in FIG. 32, a connector 2330, angular velocity sensors 2340X, 2340Y, and 2340Z, an acceleration sensor 2350, and a control IC 2360 are mounted on the substrate 2320.

The connector 2330 is electrically coupled to an external device (not shown) and is used to transmit and receive electric signals such as power and measurement data between the external device and the inertial measurement unit 2000.

The angular velocity sensor 2340X detects an angular velocity around the X-axis, the angular velocity sensor 2340Y detects an angular velocity around the Y-axis, and an angular velocity sensor 2340Z detects the angular velocity around the Z-axis. Here, the angular velocity sensors 2340X, 2340Y, and 2340Z are each any of the angular velocity sensors configured with the electronic structure according to the above-described embodiments. Also, the acceleration sensor 2350 is, for example, an acceleration sensor formed using an MEMS technology, and detects acceleration in the X-axis, Y-axis, and Z-axis directions. The acceleration sensor 2350 is any of the acceleration sensors configured with electronic structures according to the above-described embodiments.

The control IC 2360 is a micro controller unit (MCU), which incorporates a storage including a non-volatile memory, an A/D converter, and the like, and controls each section of the inertial measurement unit 2000. Here, the storage stores a program that defines the sequence and content for detecting acceleration and angular velocity, a program that digitizes the detected data and incorporates the detected data into packet data, associated data, and the like.

As described above, the inertial measurement unit 2000 includes a physical quantity sensor and the control IC 2360 which is a control circuit that controls the operation of the physical quantity sensor. According to such an inertial measurement unit 2000, the measurement accuracy can be improved by using the highly accurate detection result of the physical quantity sensor.

### 7.3. Inertial/Satellite Navigation System

As a navigation system, a global navigation satellite system (GNSS) is known. The GNSS acquires a distance from each of three navigation satellites (also called GNSS satellites) by capturing them from an aircraft. Additionally, the GNSS uses a signal from a fourth navigation satellite to synchronize time and calculate an aircraft's three-dimensional flight position.

A GNSS receiving device mounted on a moving object measures the position and the velocity of the moving object. For example, the GNSS receiving device measures distances from each of a plurality of GNSS satellites to the GNSS receiving device, and measures the position of the moving object from the measured values.

The GNSS receiving device can also be widely applied to navigation systems by combining the GNSS receiving device with a so-called inertial navigation system (INS) that uses output signals from a gyro sensor, an acceleration sensor, an IMU, and a vehicle speed sensor.

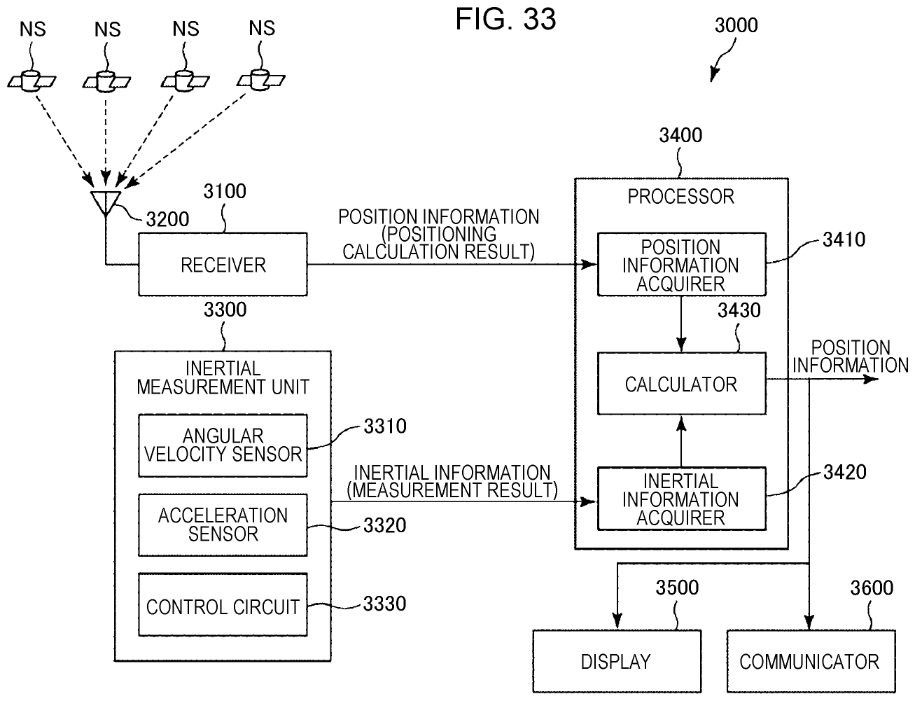

FIG. 33 is a block diagram showing an example of a configuration of an embodiment of an inertial/satellite navigation system as an example of the electronic apparatus according to the seventh embodiment.

An inertial/satellite navigation system 3000 shown in FIG. 33 is, for example, a device that is mounted on a moving object (not shown) for use, and performs positioning of the moving object. Examples of the moving object include an automobile, a motorcycle, a bicycle, a ship, a train, a person, and the like. When the inertial/satellite navigation system 3000 is mounted on a person, for example, the inertial/satellite navigation system 3000 may be incorporated into a portable information device such as a watch type device.

This inertial/satellite navigation system 3000 includes a receiver 3100 that performs positioning calculations based on satellite signals from positioning satellites NS, an inertial measurement unit 3300 that measures angular velocity and acceleration, a processor 3400 that performs a process of calculating the position of the reception point based on the positioning calculation results of the receiver 3100 and the measurement results of the inertial measurement unit 3300, a display 3500, and a communicator 3600.

The receiver 3100 is, for example, a global positioning system (GPS) receiver that receives satellite signals from positioning satellites NS (GPS satellites) through an antenna 3200 and performs positioning calculations based on orbit information and time information contained in the satellite signals. More specifically, the receiver 3100 is configured to have, for example, a radio frequency (RF) circuit, a baseband processing circuit, and the like, and the RF circuit down-converts and amplifies the satellite signals received by the antenna 3200, and the baseband processor performs positioning calculations based on orbit information and time information contained in four or more satellite signals from the RF circuit, and outputs the positioning calculation results. In addition, the receiver 3100 may output position information as data created in a national marine electronics association (NMEA) format, together with various types of information such as time information, the number of captured positioning satellites NS, and reception conditions of satellite signal strength.

The inertial measurement unit 3300 is a device that detects angular velocity around each of three axes and acceleration in each axis direction. This inertial measurement unit 3300 includes an angular velocity sensor 3310 that detects angular velocity around each of the three axes, an acceleration sensor 3320 that detects acceleration in each of the three axis directions, and a control circuit 3330 that controls the operation of the angular velocity sensor 3310 and the acceleration sensor 3320. Here, the inertial measurement unit 3300 is configured in the same manner as the inertial measurement unit 2000 described above. The inertial measurement unit 3300 then outputs inertial information including the angular velocity around each of the three axes and the acceleration in each axis direction as a measurement result.

The processor 3400 has a position information acquirer 3410 that acquires position information from the receiver 3100, an inertial information acquirer 3420 that acquires inertial information from the inertial measurement unit 3300, and a calculator 3430 that performs calculations using information from the position information acquirer 3410 and the inertial information acquirer 3420. This processor 3400 is configured to include, for example, a processor such as a central processing unit (CPU) and a memory such as a read only memory (ROM) and a random access memory (RAM), and the processor appropriately reads and executes programs stored in the memory to realize the functions of the position information acquirer 3410, the inertial information acquirer 3420, and the calculator 3430.

The position information acquirer 3410 performs statistical processing on the position information acquired from the receiver 3100 at predetermined time intervals, and outputs the results. The inertial information acquirer 3420 performs positioning calculations based on the inertial information acquired from the inertial measurement unit 3300, and outputs the results. The calculator 3430 calculates the position of the reception point based on the position information from the position information acquirer 3410 and the inertial information acquirer 3420, and outputs the calculation result. Accordingly, it is possible to generate highly accurate position information.

In addition, the position information acquirer 3410 may be omitted and the statistical processing as described above may not be performed. In this case, the calculator 3430 may use the positioning calculation results of the receiver 3100 as it is to calculate the position of the reception point as described above. In addition, the inertial information acquirer 3420 may be omitted and positioning calculations based on the measurement results of the inertial measurement unit 3300 may not be performed. In this case, the calculator 3430 may use the measurement results of the inertial measurement unit 3300 as it is to correct the positioning calculation results of the receiver 3100. Furthermore, when the reception state of the receiver 3100 is poor, the calculator 3430 may output the result of positioning calculation based on the inertial information acquired from the inertial measurement unit 3300 as position information.

The display 3500 is configured, for example, with a liquid crystal panel or the like, and has a function of displaying the position information from the calculator 3430. The communicator 3600 is configured, for example, with a communication circuit for wireless communication or wired communication, and has a function of transmitting the position information from the calculator 3430 to an external device (not shown).

As described above, the inertial/satellite navigation system 3000 includes the inertial measurement unit 3300, the receiver 3100 that performs positioning calculations based on satellite signals received from positioning satellites NS, and the processor 3400 that performs a process of calculating the position of the reception point based on the measurement results of the inertial measurement unit 3300 and the positioning calculation results of the receiver 3100. According to such an inertial/satellite navigation system 3000, positioning accuracy can be improved by using the highly accurate measurement results of the inertial measurement unit 3300.

Although the GPS satellites have been described as an example of the positioning satellites NS, the present disclosure is not limited thereto. For example, quasi-zenith satellites (QZS) and the quasi-zenith satellite system “Michibiki” using the quasi-zenith satellites, and as GNSS satellites, satellites used in other global navigation satellite systems (GNSS) such as the above-mentioned GLONASS (Russia), Galileo (European Community), and Beidou (China) can be applied. In addition, the RNSS satellites include systems that use quasi-zenith orbits other than QZSS, and in addition to IRNSS (India), DORIS (France), and Beidou (China) that can only be searched in specific regions, geostationary satellites such as the satellite-based augmentation system (SBAS) can be applied.

When a GNSS receiving device alone performs positioning, positioning becomes unstable or even impossible when the moving object is traveling in areas with many obstructions, such as areas surrounded by high-rise buildings, or inside underground passages or tunnels, because the signal from the satellite is interrupted. In response to this, positioning can be continued by using dead reckoning (autonomous navigation) technology and performing calculations in conjunction with information based on the output signals from a gyro sensor, an acceleration sensor, or an IMU. Since the gyro sensor and the acceleration sensor are configured with any of the electronic structures according to the above-described embodiments, even more accurate positioning can be realized.

### 7.4. Electronic Apparatus

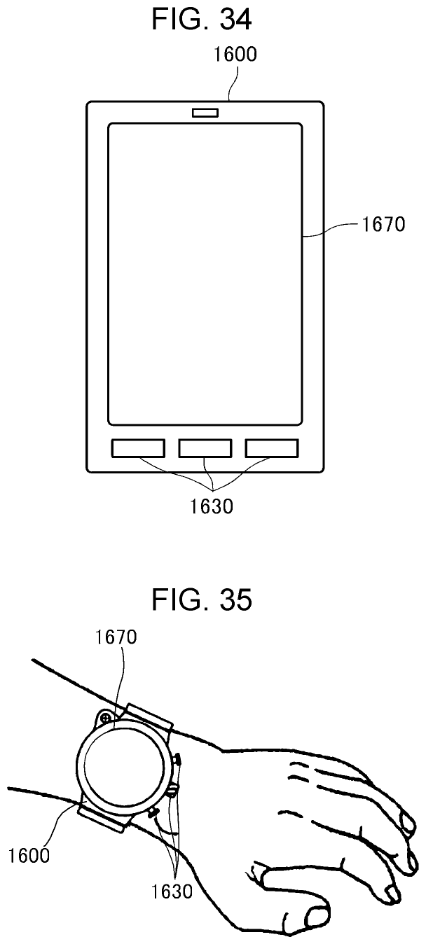

FIG. 34 is a diagram showing an example of the appearance of a smartphone as an example of the electronic apparatus 1600, and FIG. 35 is a diagram showing an example of the appearance of a wrist-worn portable device as an example of the electronic apparatus 1600. The smartphone, which is the electronic apparatus 1600 shown in FIG. 34, includes buttons as the operator 1630 and a liquid crystal display (LCD) as the display 1670. The wrist-worn portable device, which is the electronic apparatus 1600 shown in FIG. 35, includes buttons and a crown as the operator 1630 and an LCD as the display 1670. In these electronic apparatuses 1600, the electronic structure according to each of the above-described embodiments or each of the modification examples can be applied as the physical quantity detection device 1610.

Furthermore, an example of the electronic apparatus 1600 is a wristwatch-type activity tracker (active tracker), which is one type of portable electronic apparatus. A wristwatch-type activity tracker is worn on a part of the body such as the wrist with a band or the like, includes a display for digital display, and is capable of wireless communication. The electronic structure according to each of the above-described embodiments or each of the modification examples is incorporated into a wristwatch-type activity tracker.

The liquid crystal display (LCD) constituting the display 1670 displays, depending on the various detection modes, for example, position information using a GPS or a geomagnetic sensor, motion information such as amount of movement or amount of motion using an acceleration sensor or an angular velocity sensor, biological information such as pulse rate using a pulse wave sensor, or time information such as the current time.

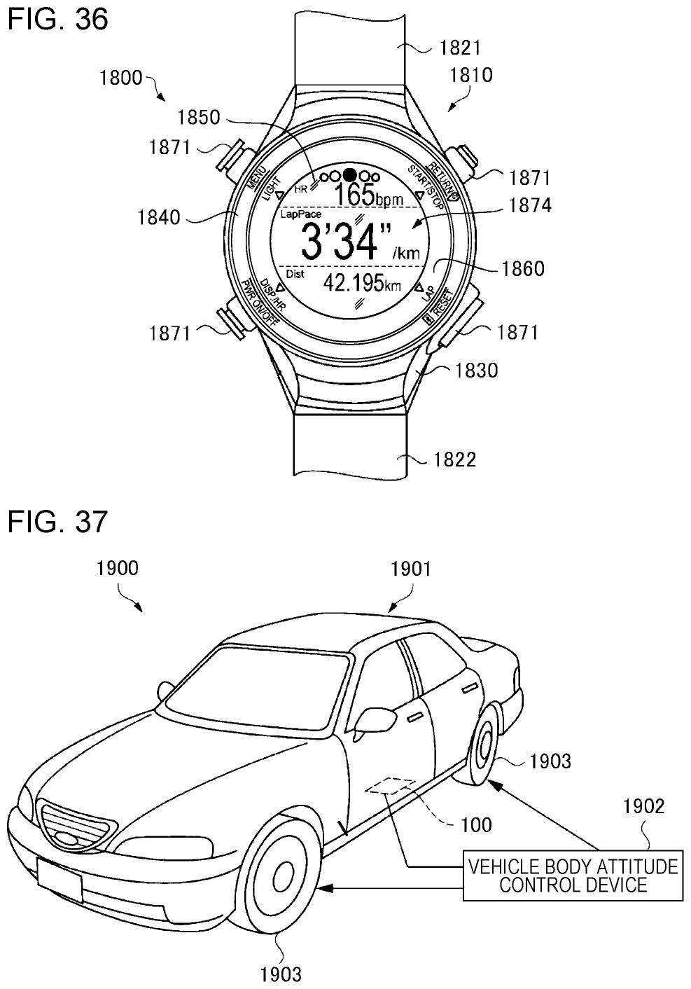

FIG. 36 is a plan view of a wrist device 1800 according to the embodiment of the portable electronic apparatus 1600. The wrist device 1800 can be widely used in wristwatch-type activity trackers such as running watches, runner's watches, runner's watches compatible with a plurality of sports such as duathlons and triathlons, outdoor watches, and GPS watches equipped with satellite positioning systems, for example GPS.

The wrist device 1800 is worn on a given part of the user's body, for example on the wrist, and can detect position information, motion information, and the like of the user. The wrist device includes a device body 1810 that is worn by a user to detect position information, motion information, and the like, and a first band 1821 and a second band 1822 that are attached to the device body 1810 for wearing the device body 1810 on the user. The wrist device 1800 can be provided with a function of detecting biological information such as pulse wave information and a function of acquiring time information, in addition to the position information and the motion information of the user.

The device body 1810 has a bottom case (not shown) disposed on the side that is worn by the user as a case, and a top case 1830 having an opening that opens to the front side disposed on the opposite side to the side that is worn by the user. Here, the bottom case and the top case 1830 constitute a case. A bezel 1840 is provided on the outer side of the opening located in the top case 1830 on the front side of the device body 1810, and a windshield 1850 is provided on the inside of the bezel 1840, disposed side by side with the bezel 1840, as a top panel or an outer wall that protects the internal structure. The windshield 1850 is, for example, a glass plate, functions as a light-transmitting cover, and is disposed to close the opening of the top case 1830. A plurality of operation buttons serving as an operator 1871 are provided on the side surface of the top case 1830 of the device body 1810. Further, the bezel 1840 can be provided with a display that is visible from the front side.

In addition, the device body 1810 has a display 1874 including a liquid crystal display (LCD) or the like, which is disposed directly below the windshield 1850, and a moisture absorbing member 1860 which is disposed between the outer edge portion of the windshield 1850 and the display 1874, and the display 1874 and the moisture absorbing member 1860 are accommodated in a case. Further, the moisture absorbing member 1860 can be provided with a display that is visible from the front side. The device body 1810 may be configured such that the user can view the display on the display 1874 and the display on the moisture absorbing member 1860 through the windshield 1850. In other words, the wrist device 1800 may display various types of information such as detected position information, motion information, or time information on the display 1874 and present the display to the user from the top side of the device body 1810. In addition, a pair of band mounting sections (not shown) that are coupling sections between the first band 1821 and the second band 1822 are provided on both sides of the bottom case.

An acceleration sensor is mounted on the wrist device 1800. The acceleration sensor detects acceleration in three axis directions that intersect each other, ideally orthogonal to each other, and outputs an acceleration signal according to the magnitude and the direction of the detected three-axis acceleration. As the acceleration sensor, the electronic structure according to each of the above-described embodiments or each of the modification examples can be applied. Also, an angular velocity sensor is mounted on the wrist device 1800. The angular velocity sensor detects angular velocity in three axis directions that intersect each other, ideally orthogonal to each other, and outputs an angular velocity signal according to the magnitude and the direction of the detected three-axis angular velocity. As the angular velocity sensor, the electronic structure according to each of the above-described embodiments or each of the modification examples can be applied.

### 8. Eighth Embodiment

Next, an electronic apparatus according to an eighth embodiment will be described with reference to the drawings. FIG. 37 is a perspective view showing a configuration of an automobile as an example of a moving object according to the eighth embodiment. As shown in FIG. 37, the electronic structure 100 according to according to each of the above-described embodiments or each of the modification examples is mounted on an automobile 1900, and the attitude of a vehicle body 1901 can be detected by the electronic structure 100, for example. The physical quantity signal output from the electronic structure 100 is supplied to a vehicle body attitude control device 1902, which serves as an attitude controller that controls the attitude of the vehicle body. The vehicle body attitude control device 1902 detects the attitude of the vehicle body 1901 based on the signal, and can control the hardness or softness of the suspension or control the brakes of individual wheels 1903 according to the detection result. In addition, the electronic structure 100 can be widely applied to electronic control units (ECUs) such as keyless entry, an immobilizer, a car navigation system, a car air conditioner, an anti-lock braking system (ABS), airbags, a tire pressure monitoring system (TPMS), engine controls, control devices for inertial navigation for autonomous driving, and battery monitors for a hybrid vehicle and an electric vehicle.

In addition to the above examples, the electronic structure 100 applied to a moving object can be used, for example, in attitude control of bipedal robots, trains, or the like, attitude control of remote-controlled or autonomous flying bodies such as radio-controlled airplanes, radio-controlled helicopters, and drones, and attitude control of agricultural machinery, construction machinery, or the like. As described above, the electronic structure 100 and the respective controllers are incorporated to realize attitude control of various moving objects.

In the present disclosure, some configurations may be omitted or each embodiment or modification example may be combined within the scope of the features and effects described in the present application.

The present disclosure is not limited to the above-described embodiment, and various modifications are possible. For example, the present disclosure includes configurations that are substantially the same as the configurations described in the embodiments. A substantially identical configuration is, for example, a configuration having the same function, method, and result, or a configuration having the same purpose and effect. The present disclosure also includes configurations in which non-essential parts of the configurations described in the embodiments are replaced. Furthermore, the present disclosure includes configurations that have the same effects as the configurations described in the embodiments or that can achieve the same purpose. Furthermore, the present disclosure includes configurations in which publicly known technology is added to the configurations described in the embodiments.

The following can be derived from the above-described embodiments and modification examples.

An electronic structure according to an aspect includes a circuit element, and a functional element disposed at a position overlapping the circuit element in a plan view in a Z-axis direction along a Z-axis, where three mutually orthogonal axes are an X-axis, a Y-axis, and the Z-axis, in which, between the circuit element and the functional element, a first protrusion group including a plurality of first protrusions disposed in an X-axis direction along the X-axis and a second protrusion group including a plurality of second protrusions disposed in the X-axis direction are provided, the circuit element and the functional element are coupled through the first protrusion group and the second protrusion group, a gap is provided between the first protrusion group and the second protrusion group, and the gap includes a first space provided from an end of the circuit element on a negative side of the X-axis to an end of the circuit element on a positive side of the X-axis.

The electronic structure includes the first space between the circuit element and the functional element, which is provided from the end of the circuit element on the negative side of the X-axis to the end of the circuit element on the positive side of the X-axis, and therefore the flow of gas such as atmosphere can be promoted in the first space, and the heat insulation effect between the circuit element and the functional element can be improved.

In the electronic structure according to the aspect, between the first protrusion group and the second protrusion group, a third protrusion group including a plurality of third protrusions disposed in the X-axis direction in the plan view may be provided, and the circuit element and the functional element may be coupled through the third protrusion group.

In the electronic structure, the bending of the functional element can be reduced and the flatness of the functional element can be improved, compared to when the functional element is supported by two protrusion groups.

In the electronic structure according to the aspect, the first space may be provided between the first protrusion group and the third protrusion group.

In the electronic structure, the flow of gas such as atmosphere can be promoted in the first space, and the heat insulation effect between the circuit element and the functional element can be improved.

In the electronic structure according to the aspect, a second space may be provided between the second protrusion group and the third protrusion group, and the second space may be provided from the end of the circuit element on the negative side of the X-axis to the end of the circuit element on the positive side of the X-axis.

In the electronic structure, the flow of gas such as atmosphere can be promoted in the first space and the second space, and the heat insulation effect between the circuit element and the functional element can be further improved.

In the electronic structure according to the aspect, when an interval between the circuit element and the functional element is denoted by S, 18 μm≤S may be satisfied.

In the electronic structure, the flow of gas can be promoted in the first space, and the heat insulation effect between the circuit element and the functional element can be improved.

In the electronic structure according to the aspect, 18 μm≤S≤70 μm may be satisfied.

In the electronic structure, the flow of gas can be promoted in the first space, and the heat insulation effect between the circuit element and the functional element can be improved.

In the electronic structure according to the aspect, when an interval between the first protrusion group and the third protrusion group is denoted by L1 and a width of the first protrusion group is denoted by L2, 0.15<L2/L1<1.1 may be satisfied.

In the electronic structure, it is possible to stably support the functional element while ensuring the width of the first space.

In the electronic structure according to the aspect, 0.25<L2/L1<0.85 may be satisfied.

In the electronic structure, it is possible to stably support the functional element while ensuring the width of the first space.

The electronic structure according to the aspect may further include a first bonding section that bonds a bottom surface of the functional element on a side of the circuit element and the first protrusion, in which the first bonding section may include a first eutectic layer having, as a main component, a eutectic alloy of a first metal having aluminum as a main component, a second metal having germanium or silicon, and a third metal having titanium or nickel.

In the electronic structure, the bonding strength between the functional element and the first protrusion can be improved.

The electronic structure according to the aspect may further include a second bonding section that bonds the bottom surface of the functional element on the side of the circuit element and the third protrusion, in which the second bonding section may include a second eutectic layer that diffuses into an inside of a base substrate of the functional element and is electrically coupled to the base substrate, and the second eutectic layer may have, as a main component, a eutectic alloy of a first metal having aluminum as a main component, a second metal having germanium or silicon, and a third metal having titanium or nickel.

In the electronic structure, the second bonding section can bond the functional element and the third protrusion, and the second bonding section and the base substrate can be electrically coupled.

In the electronic structure according to the aspect, the functional element may be any one of a MEMS sensor element, a MEMS vibration element, and a MEMS element.

An inertial measurement unit according to an aspect includes the above-described electronic structure, in which the functional element is an inertial sensor element.

An electronic apparatus according to an aspect includes the above-described electronic structure.

A moving object according to an aspect includes the above-described electronic structure.

What is claimed is:

1. An electronic structure comprising:
a circuit element; and
a functional element disposed at a position overlapping the circuit element in a plan view in a Z-axis direction along a Z-axis, where three mutually orthogonal axes are an X-axis, a Y-axis, and the Z-axis, wherein,
between the circuit element and the functional element, a first protrusion group including a plurality of first protrusions disposed in an X-axis direction along the X-axis and a second protrusion group including a plurality of second protrusions disposed in the X-axis direction are provided,
the circuit element and the functional element are coupled through the first protrusion group and the second protrusion group,
a gap is provided between the first protrusion group and the second protrusion group, and
the gap includes a first space provided from an end of the circuit element on a negative side of the X-axis to an end of the circuit element on a positive side of the X-axis.

2. The electronic structure according to claim 1, wherein
between the first protrusion group and the second protrusion group, a third protrusion group including a plurality of third protrusions disposed in the X-axis direction in the plan view is provided, and
the circuit element and the functional element are coupled through the third protrusion group.

3. The electronic structure according to claim 2, wherein
the first space is provided between the first protrusion group and the third protrusion group.

4. The electronic structure according to claim 3, wherein
a second space is provided between the second protrusion group and the third protrusion group, and
the second space is provided from the end of the circuit element on the negative side of the X-axis to the end of the circuit element on the positive side of the X-axis.

5. The electronic structure according to claim 1, wherein
when an interval between the circuit element and the functional element is denoted by S, 18 μm≤S is satisfied.

6. The electronic structure according to claim 5, wherein
18 μm≤s≤70 μm is satisfied.

7. The electronic structure according to claim 2, wherein
when an interval between the first protrusion group and the third protrusion group is denoted by L1 and a width of the first protrusion group is denoted by L2, 0.15<L2/L1<1.1 is satisfied.

8. The electronic structure according to claim 7, wherein
0.25<L2/L1<0.85 is satisfied.

9. The electronic structure according to claim 3, further comprising:
a first bonding section that bonds a bottom surface of the functional element on a side of the circuit element and the first protrusion, wherein
the first bonding section includes a first eutectic layer having, as a main component, a eutectic alloy of a first metal having aluminum as a main component, a second metal having germanium or silicon, and a third metal having titanium or nickel.

10. The electronic structure according to claim 9, further comprising:
a second bonding section that bonds the bottom surface of the functional element on the side of the circuit element and the third protrusion, wherein
the second bonding section includes a second eutectic layer that diffuses into an inside of a base substrate of the functional element and is electrically coupled to the base substrate, and
the second eutectic layer has, as a main component, a eutectic alloy of a first metal having aluminum as a main component, a second metal having germanium as a main component, and a third metal having titanium as a main component.

11. The electronic structure according to claim 1, wherein
the functional element is any one of a MEMS sensor element, a MEMS vibration element, and a MEMS element.

12. An inertial measurement unit comprising:
the electronic structure according to claim 1, wherein the functional element is an inertial sensor element.

13. An electronic apparatus comprising:
the electronic structure according to claim 1.

14. A moving object comprising:
the electronic structure according to claim 1.
